(19) United States
(12) Patent Application Publication
(10) Pub. No.: US 2010/0074001 A1
(43) Pub. Date: Mar. 25, 2010

(54) INFORMATION RECORDING/REPRODUCING DEVICE

(75) Inventors: Kohichi Kubo, Yokohama-shi (JP); Takayuki Tsukamoto, Kawasaki-shi (JP); Shinya Aoki, Yokohama-shi (JP); Takahiro Hirai, Yokohama-shi (JP); Chikayoshi Kamata, Kawasaki-shi (JP); Toshiro Hiraoka, Yokohama-shi (JP)

Correspondence Address: CHARLES N.J. RUGGIERO;OHLANDT, GREELEY, RUGGIERO & PERLE, L.L.P., ONE LANDMARK SQUARE, 10th FLOOR, STAMFORD, CT, 06901-2682, US

(73) Assignee: KABUSHIKI KAISHA TOSHIBA

(21) Appl. No.: 12/563,703

(22) Filed: Sep. 21, 2009

Related U.S. Application Data
(63) Continuation-in-part of application No. PCT/JP2007/061829, filed on Jun. 12, 2007.

(30) Foreign Application Priority Data
Mar. 30, 2007 (JP) 2007-095341

(51) Int. Cl. G11C 11/56; H01L 45/00

(52) U.S. Cl. 365/163; 257/2

(57) ABSTRACT

The information recording/reproducing device includes a stacked structure which is comprised of an electrode layer and a recording layer, a buffer layer which contacts with the recording layer and a recording circuit which records data to the recording layer by generating a phase change in the recording layer. The recording layer is comprised of a complex compound having two cations, and one of the cations is a transition element having “d” orbit where electrons are incompletely filled. The recording layer is comprised of CuₓA_{y}X_{z} (0.1≦x≦1.1, 0.9≦y≦1.1, 1.8≦z≦2.2), and includes a first chemical compound having a delafossite structure. The buffer layer is comprised of one of M₃N₄, M₃N₅, MN₂, M₄O₇, MO₂ and M₂O₅.

### CROSS REFERENCE TO RELATED APPLICATIONS

This is a Continuation Application of PCT Application No. PCT/JP2007/061829, filed Jun. 12, 2007, which was published under PCT Article 21(2) in Japanese.

This application is based upon and claims the benefit of priority from prior Japanese Patent Application No. 2007-095341, filed Mar. 30, 2007, the entire contents of which are incorporated herein by reference.

### BACKGROUND OF THE INVENTION

1. Field of the Invention

The present invention relates to an information recording/reproducing device with a high recording density.

2. Description of the Related Art

In recent years, compact portable devices have been widely used worldwide and, at the same time, a demand for a small-sized and large-capacity nonvolatile memory has been expanding rapidly along with the extensive progress of a high-speed information transmission network. Among them, particularly a NAND type flash memory and a small-sized HDD (hard disk drive) have rapidly evolved in recording density, and accordingly, they now form a large market.

Under such circumstances, some ideas for a new memory have been proposed, with the goal of greatly increasing the limit of recording density.

For instance, PRAM (phase change memory) adopts a principle in which materials capable of taking two conditions, an amorphous condition (ON) and crystalline condition (OFF), are used as recording materials, and these two conditions are caused to correspond to binary data “0” and “1” to record data.

Write/erase is performed in such a way that, for instance, the amorphous condition is prepared by applying a large power pulse to the recording material, and the crystalline condition is prepared by applying a small power pulse to the recording material.

A read is performed by causing a small read current to flow in the recording material to the degree that the write/erase is not generated, followed by measuring an electric resistance of the recording material. The resistance value of the recording material in the amorphous condition is larger than the resistance value of the recording material in the crystalline condition, and its ratio is in the degree of 10³.

The greatest feature of the PRAM lies in a point that, even though element size is reduced to about 10 nm, the element can be operated. In this case, since the recording density of about 10 Tbpsi (tera bytes per square inch) can be realized, and accordingly, this is one of candidates for realizing increased recording density (for instance, refer to T. Gotoh, K. Sugawara and K. Tanaka, Jpn. J. Appl. Phys., 43, 6B, 2004, L818).

Further, a new memory has been reported which is different from the PRAM but has a very similar operation principle to the PRAM (for instance, refer to A. Sawa, T. Fuji, M. Kawasaki and Y. Tokura, Appl. Phys. Lett., 85, 18, 4073 (2004)).

According to this report, a representative example of a recording material to record data is nickel oxide, in which, like the PRAM, the large power pulse and the small power pulse are used for performing the write/erase. There has been reported an advantage that the power consumption at the time of the write/erase becomes small as compared with the PRAM.

Until now, although the details of an operation mechanism of the new memory are not clear, reproducibility is confirmed, and thus this is noticed as one of the candidates for the increased recording density. Further, some research groups are attempting to clarify the operation mechanism.

In addition thereto, proposed is a MEMS memory using MEMS (micro electro mechanical system) technology (for instance, refer to P. Vettiger, G. Cross, M. Despont, U. Drechsler, U. Durig, B. Gotsmann, W. Haberle, M. A. Lants, H. E. Rothuizen, R. Stutz and G. K. Binng, IEEE Trans. Nanotechnology 1, 39(2002)).

In particular, the MEMS memory, called Millipede, has a structure in which a plurality of array shaped cantilevers face a recording medium to which an organic substance is applied, and a probe at a tip of the cantilever comes into contact with the recording medium with appropriate pressure.

A write is performed by selectively controlling the temperature of a heater added to the probe. That is, when increasing the temperature of the heater, the recording medium is softened, and then, depressions are formed on the recording medium because the probe forms dents in the recording medium.

A read is performed by scanning the probe on a surface of the recording medium while causing a current to flow through the probe to the degree that the recording medium is not softened. When the probe sinks into the depression of the recording medium, temperature of the probe decreases, and the resistance value of the heater increases, so that it is possible to sense the data by reading this change of resistance value.

The greatest feature of the MEMS memory such as the Millipede lies in a point that since it is not necessary for each recording part to provide wiring to record bit data, the recording density can be improved remarkably. Under existing circumstances, a recording density of about 1 Tbps has already been achieved (for instance, refer to P. Vettiger, T. Albrecht, M. Despond, U. Drechsler, U. Durig, B. Gotsmann, D. Jubin, W. Haberle, M. A. Lants, H. E. Rothuizen, R. Stutz, D. Wiesmann and G. K. Binng, P. Bachtold, G. Cherubini, C. Hagleitner, T. Loeliger, A. Pantazi, H. Pozidis and E. Eleftheriou, in Technical Digest, IEDM03 pp. 763 to 766).

Further, subsequent to the Millipede, recently, performed are attempts to achieve a large improvement concerning power consumption, recording density or working speed while combining the MEMS technique with a new recording principle.

For instance, proposed is a system in which a ferroelectric layer is provided on the recording medium, and recording of the data is performed by causing dielectric polarization in the ferroelectric layer by applying a voltage to the recording medium. Theoretically, this system is predicted to be able to utilize one crystal as a unit (recording minimum unit) for recording one byte of data.

If the recording minimum unit is equivalent to one unit cell of the crystal of the ferroelectric layer, the recording density rises to a phenomenal approx. 4 Pbpsi (peta bytes per square inch).

Recently, based on development of a read system using SNDM (scanning nonlinear dielectric microscope), the new memory has advanced considerably toward practical use (for instance, refer to A. Onoue, S. Hashimoto, Y. Chu, Mat. Sci. Eng. B120, 130 (2005)).

### BRIEF SUMMARY OF THE INVENTION

An information recording/reproducing device according to an aspect of the present invention comprises a stacked structure which is comprised of an electrode layer and a recording layer, a buffer layer which contacts with the electrode layer, and a recording circuit which records data to the recording layer by generating a phase change in the recording layer. The recording layer is comprised of a complex compound having cations, and one of the cations is a transition element having “d” orbit where electrons are incompletely filled. The recording layer is comprised of CuₓA_{y}X_{z} (0.1≦x≦1.1, 0.9≦y≦1.1, 1.8≦z≦2.2), where A includes one element selected from a group of Al, Ga, Sc, In, Y, La, Pr, Nd, Sm, Eu, Gd, Tb, Dy, Ho, Er, Tm, Yb, Lu, Ti, Ge, Sn, V, Cr, Mn, Fe, Co, Ni, Nb, Ta, Mo, W, Ru, Rh, and Pd, and X includes one element selected from a group of O, F, N, and S. The recording layer includes a first chemical compound having a delafossite structure. The buffer layer is comprised of one of M₃N₄, M₃N₅, MN₂, M₄O₇, MO₂ and M₂O₅, where M includes one element selected from Si, Ge, Sn, Zr, Hf, Nb, Ta, Mo, W, Ce, and Tb.

### BRIEF DESCRIPTION OF THE SEVERAL VIEWS OF THE DRAWING

FIGS. 1 to 3 are views, each showing a recording principle.

FIG. 4 is a view showing a probe memory.

FIG. 5 is a view showing a segmentation of a recording medium.

FIG. 6 is a view showing the condition of recording.

FIGS. 7 to 10 are views, each showing a recording operation.

FIG. 11 is a view showing a semiconductor memory.

FIG. 12 is a view showing a memory cell array.

FIG. 13 is a view showing a memory cell.

FIGS. 14 and 15 are views, each showing a memory cell array.

FIG. 16 is a view showing an application example for a flash memory.

FIGS. 17 to 20 are views, each showing a NAND cell unit.

FIGS. 21 and 22 are views, each showing a NOR cell.

FIGS. 23 to 25 are views, each showing a 2-transistor cell unit.

FIG. 26 is a view showing a recording principle.

FIG. 27 is a view showing a delafossite structure.

FIGS. 28 and 29 are views, each showing an example of a memory cell array structure.

FIGS. 30 and 31 are views, each showing a modified example of a recording layer.

### DETAILED DESCRIPTION OF THE INVENTION

1. Outline

An information recording/reproduction device according to an example of the present invention is provided with a recording part having a stacked structure comprised an electrode layer and a recording layer, and a buffer layer added to the recording layer. The recording layer is comprised a complex compound having at least two kinds of cations, at least one of which is a transition element having a “d” orbit where electrons are incompletely filled.

The recording layer is comprised a material represented by CuₓA_{y}X_{z} (0.1≦x≦1.1, 0.9≦y≦1.1, 1.8≦z≦2.2), where A is at least one element selected from a group of Al, Ga, Sc, In, Y, La, Pr, Nd, Sm, Eu, Gd, Tb, Dy, Ho, Er, Tm, Yb, Lu, Ti, Ge, Sn, V, Cr, Mn, Fe, Co, Ni, Nb, Ta, Mo, W, Ru, Rh, and Pd. It is more preferable for A to be at least one element selected from a group of V, Cr, Mn, Fe, Co, and Ni. When using these elements, electron condition inside the crystal is easy to control.

X is at least one element selected from a group of O, F, N, and S. Molar ratios x, y and z fulfill 0.5≦x≦1.1, 0.9≦y≦1, 1.8≦z≦2.2, respectively.

Meanwhile, concerning the molar ratios x, y and z of the above-described material (CuₓA_{y}X_{z}), the lower limit of a numeric range is set to maintain the crystal structure, and the upper limit thereof is set to control the electron condition inside the crystal.

Further, the material used for the recording layer is to be the crystal having the delafossite structure.

By using the above material for the recording layer, it is possible to realize the recording density of the Pbpsi (peta bytes per square inch) class in principle, and further to achieve low power consumption.

2. Fundamental Principle of Recording/Reproduction

Explanation will next be made about the fundamental principle of recording/reproduction of information in the information recording/reproducing device according to an example of the present invention.

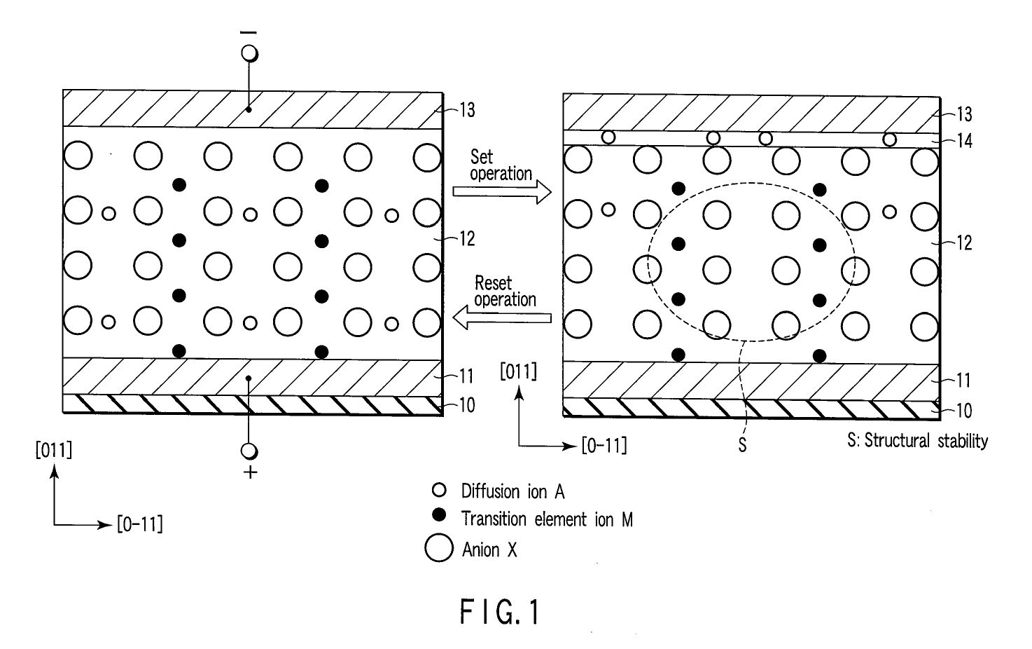

FIG. 1 shows a structure of the recording part.

Reference numeral 10 indicates a buffer layer, 11 indicates an electrode layer, 12 indicates a recording layer, and 13 indicates an electrode layer (or protection layer). Small white circles inside the recording layer 12 represent diffusion ions Cu, and small black circles represent transition element ions A. Further, large white circles represent anions X.

When a potential gradient is generated inside the recording layer 12 by applying a voltage to the recording layer 12, part of diffusion ions moves to the interior of the crystal structure. Consequently, in the example of the present invention, the information recording is performed in such a way that an initial condition of the recording layer 12 is set to an insulator (high resistance condition), and the potential gradient causes the phase change of the recording layer 12 to make the recording layer 12 conductive (low resistance condition).

Here, in the present specification, the high resistance condition is defined as the reset condition, and the low resistance condition is defined as the set condition. However, this definition is used to simplify the following explanation, and depending on selection of the material or manufacturing method, the reverse case is possible. That is, the low resistance condition is defined as the reset condition (initial) and the high resistance condition is defined as the set condition. Needless to say, such a case is also included in the scope of the present invention.

Firstly, for instance, prepared is a condition where the electric potential of the electrode layer 13 is lower than the electric potential of the electrode layer 11. A negative electric potential may be supplied to the electrode layer 13 when the electrode layer 11 has a fixed electric potential (for instance, ground potential).

At this time, part of the diffusion ions inside the recording layer 12 moves to the electrode layer (cathode) 13 side, so that the diffusion ions inside the recording layer (crystal) 12 decrease relatively to the anions. The diffusion ions having moved to the electrode layer 13 side receive electrons from the electrode layer 13, and form a metal layer 14 after separating out as metal.

Inside the recording layer 12, the anions become excessive. As a result, the excess anions increase the valence of the ions of the transition element inside the recording layer 12. That is, since the recording layer 12 becomes conductive by implantation of carriers, the information recording (set operation) is completed.

Information reproduction is performed easily by detecting the resistance value of the recording layer 12 while causing a current pulse to flow through the recording layer 12. However, it is necessary for the current pulse to be a minute value to the degree that the materials constituting the recording layer 12 do not cause the phase change.

The above process is a kind of electrolysis, and thus it is conceivable that an oxidizing agent is generated by electrochemical oxidation at the electrode layer (anode) 11 side, while a reducing agent is generated by electrochemical reduction at the electrode layer (cathode) 13 side.

For this reason, in order to return the low resistance condition of information recording to the initial high resistance condition, for instance, an oxidation-reduction reaction of the recording layer 12 is promoted by performing Joule-heating of the recording layer 12 with a large-current pulse. That is, the recording layer 12 returns to the insulator due to residual heat after disconnection of the large-current pulse (reset operation).

However, in order to put the operation principle to practical use, it should be confirmed that the reset operation is not generated at room temperature (securing a sufficiently long retention time), and the power consumption of the reset operation is sufficiently small.

The former condition can be met in such a way that the coordination number of the diffusion ions is made small (ideally, 2 or less) or the valence of the diffusion ions is made bivalent or higher, or alternatively, the valence of the anions is made to increase (ideally, made trivalent or higher).

Further, the latter condition can be met in such a way that the valence of the diffusion ions is made bivalent or less in order not to cause crystal collapse, which provides a material that enables multiple paths along which the diffusion ions may move in the recording layer (crystal) 12.

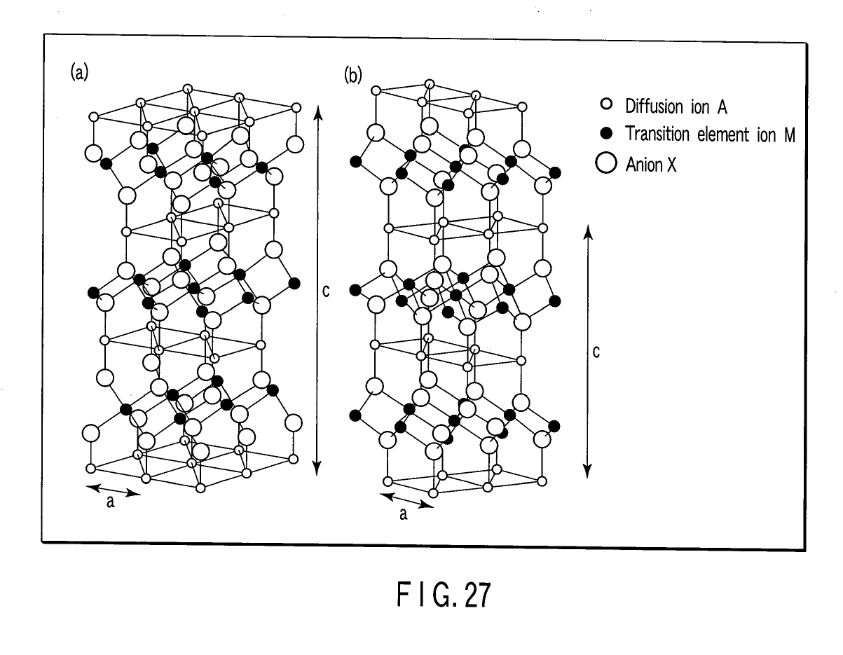

As such a recording layer 12, the element and the crystal structure described above may be adopted. In particular, the delafossite structure, as shown in FIG. 27, has a structure in which A ions are aligned in a two-dimensional plane shape. For this reason, there are movement paths of the A ions in the direction in 360 degrees of the two-dimensional plane, and the delaffosite structure is in bicoordination. Accordingly, it is the optimum structure to fulfill the above-described conditions. Further, CuCoO₂ is the most preferable material for the recording layer because the movement path of the diffusion ions forms the most suitable two-dimensional plane.

Meanwhile, as shown in FIGS. 27A and 27B, two delafossite structures exist and the M ion has octahedral hexacoordination. However, in the present invention, the case where the M ions have triangular column-shaped hexacoordination is also included in the delafossite structure.

Further, in any of the above-described delafossite structures, division of the element of the site of Cu and the site of A is necessary for crystallization. In order to cope with this, the delafossite structure needs to exist in the range represented by the following composition formula:

CuₓA_{y}X_{z} (0.1≦x≦1.1, 0.9≦y≦1.1, 1.8≦z≦2.2)

In this formula, the portion particularly represented by A_{y}X_{z} is a portion configuring a skeleton of the crystal, and Cu is the ions moving inside the skeleton. Therefore, “y” and “z” need to be close to a fixed ratio stoichiometric composition, and “x” may vary in a relatively wide range.

Meanwhile, since the oxidizing agent is generated in the electrode layer (anode) 11 side after the set operation, the electrode layer 11 is preferably comprised a material which hardly oxidizes (for instance, an electrically-conductive nitride or electrically-conductive oxide).

Further, the electrode layer 11 is preferably comprised a material having no ion conductivity.

The materials with the above properties are as follows. Among them, from the viewpoint of comprehensive performance coupled with favorable electric conductivity, LaNiO₃ is the most preferable material.
MN

M is at least one element selected from a group of Ti, Zr, Hf, V, Nb, and Ta. N is nitrogen.
MOₓ

M is at least one element selected from a group of Ti, V, Cr, Mn, Fe, Co, Ni, Cu, Zr, Nb, Mo, Ru, Rh, Pd, Ag, Hf, Ta, W, Re, Ir, Os, and Pt. Molar ratio x fulfills 1≦x≦4.
AMO₃

A is at least one element selected from a group of La, K, Ca, Sr, Ba, and Ln (Lanthanide).

M is at least one element selected from a group of Ti, V, Cr, Mn, Fe, Co, Ni, Cu, Zr, Nb, Mo, Ru, Rh, Pd, Ag, Hf, Ta, W, Re, Ir, Os, and Pt.

O is oxygen.
B₂MO₄

B is at least one element selected from a group of K, Ca, Sr, Ba, and Ln (Lanthanide).

M is at least one element selected from a group of Ti, V, Cr, Mn, Fe, Co, Ni, Cu, Zr, Nb, Mo, Ru, Rh, Pd, Ag, Hf, Ta, W, Re, Ir, Os, and Pt.

O is oxygen.

Further, the reducing agent is generated in the electrode layer (cathode) 13 side after the set operation, and therefore, the electrode layer 13 preferably has a function of preventing the recording layer 12 from reacting with atmospheric air.

Such materials are, for instance, semiconductors such as amorphous carbon, diamond-like carbon, and SnO₂.

The electrode layer 13 may function as the protection layer to protect the recording layer 12, or the protection layer may be provided in place of the electrode layer 13. In this case, the protection layer may be an insulator or a conductive material. Further, in order to efficiently perform heating of the recording layer 12 in the reset operation, a heater layer (material having resistivity of approximately 10⁻⁵ Ωcm or more) is preferably provided at the cathode side, in this case, at the electrode layer 13 side.

Further, the direction of the ion movement path of the recording material of the present invention is preferably aligned vertically to a film surface. For this purpose, it is necessary for the recording layer 12 to be oriented in a vertical axis with respect to the C axis of the delafossite structure.

Accordingly, in the present invention, a buffer layer 10 is added to the electrode layer 11 to control the orientation.

The buffer layer (underlying layer) 10 is comprised materials represented by at least M₃N₄, M₃N₅, MN₂, or M₄O₇, MO₂, M₂O₅ (where M is at least one element selected from Si, Ge, Sn, Zr, Hf, Nb, Ta, Mo, W, Ce, and Tb).

Further, the mobility of the ions is different between in the inside of the crystal structure and in the peripheral portion of the crystal grain. Therefore, in order to equalize the recording/erase properties at different positions by utilizing movement of diffusion ions inside the crystal structure, the recording layer preferably has the condition of polycrystallinity or the condition of single crystallinity. When the recording layer is in the polycrystallinity condition, considering film-formability, the size in the cross sectional direction of the recording film of the crystal grain preferably follows a distribution having a single peak, and its average is 3 nm or more. When the average size of the crystal grain size is 5 nm or more, it is more preferable because film-formation is easier; and when the average size of the crystal grain size is 10 nm or more, it is further preferable because it is possible to further equalize the recording/erase properties at different positions.

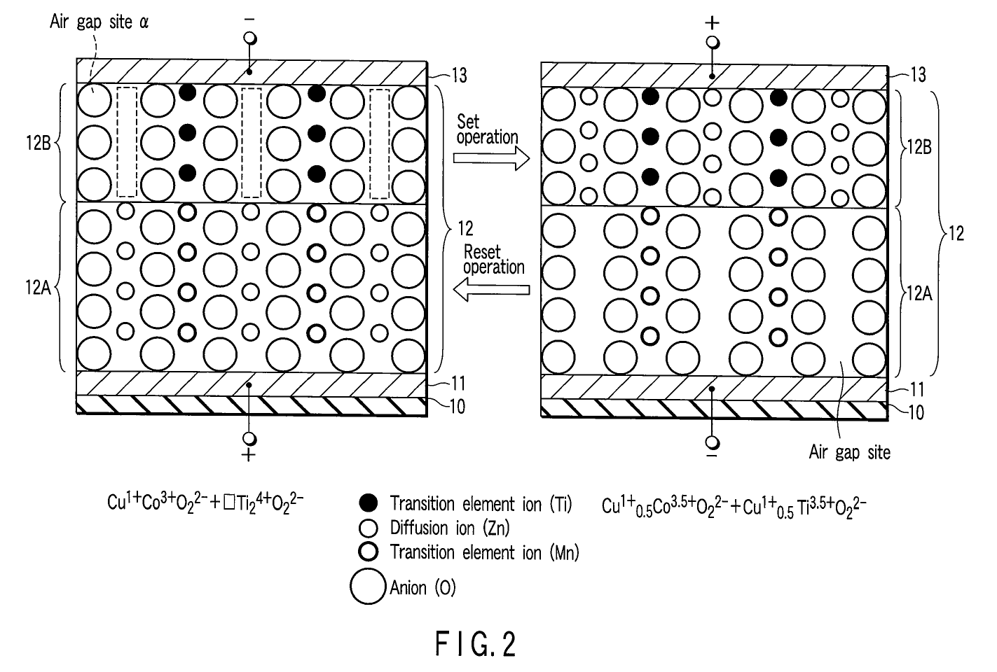

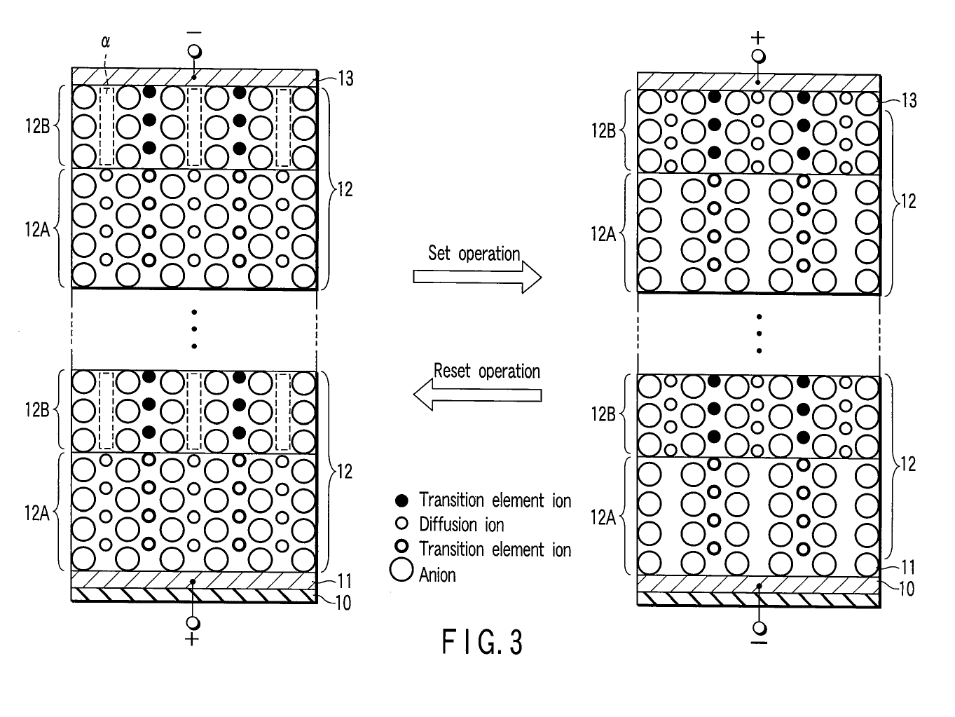

Further, as shown in FIG. 2, a second chemical compound 12B may be layered on a recording layer (the first chemical compound) 12A. Furthermore, as shown in FIG. 3, a recording layer 12 comprised the first and second chemical compounds 12A, 12B may be stacked in a multi-layered shape.

The second chemical compound 12B characteristically has a vacant site α. Taking the vacant site α to be represented by [symbol] , the second chemical compound 12B is represented by the following formulas:
Chemical formula: [symbol] ₓMZ₂

where [symbol] is the vacant site in which the above-described X is accommodated, M includes at least one element selected from Ti, V, Cr, Mn, Fe, Co, Ni, Nb, Ta, Mo, W, Re, Ru, and Rh, Z includes at least one element selected from O, S, Se, N, Cl, Br, and I, and x falls in the range of 0.3≦x≦1.
Chemical formula: [symbol] ₓMZ₃

where [symbol] is the vacant site in which the above-described X is accommodated, M includes at least one element selected from Ti, V, Cr, Mn, Fe, Co, Ni, Nb, Ta, Mo, W, Re, Ru, and Rh, Z includes at least one element selected from O, S, Se, N, Cl, Br, and I, and x falls in the range of 1≦x≦2.
Chemical formula: [symbol] ₓMZ₄

where [symbol] is the vacant site in which the above-described X is accommodated, M includes at least one element selected from Ti, V, Cr, Mn, Fe, Co, Ni, Nb, Ta, Mo, W, Re, Ru, and Rh, Z includes at least one element selected from O, S, Se, N, Cl, Br, and I, and x falls in the range of 1≦x≦2.
Chemical formula: [symbol] ₓMPO_{z}

where [symbol] is the vacant site in which the above-described X is accommodated, M includes at least one element selected from Ti, V, Cr, Mn, Fe, Co, Ni, Nb, Ta, Mo, W, Re, Ru, and Rh, P is phosphorus element, O is oxygen element, x falls in the range of 0.3≦x≦3, and z falls in the range of 4≦z≦6.

These substances have the function of accommodating ions emitted from the first chemical compound 12A, facilitating movement of the ions, and realizing improvement of reversibility.

The second chemical compound 12B preferably has one of a hollandite structure, ramsdellite structure, anatase structure, brookite structure, pyrolusite structure, ReO₃ structure, MoO_{1.5}PO₄ structure, TiO_{0.5}PO₄ structure, FePO₄ structure, βMnO₂ structure, γMnO₂ structure, λMnO₂ structure, and ilmenite structure. The ilmenite structure is the most preferable among them, which has a two-dimensional structure for movement of the ions like the delafossite structure, and has an accommodating site of the ions in its surface.

Note that the C axis of the crystal of the recording layer 12 is preferably oriented in the horizontal direction or in the range of 45 degrees from the horizontal direction to the film surface.

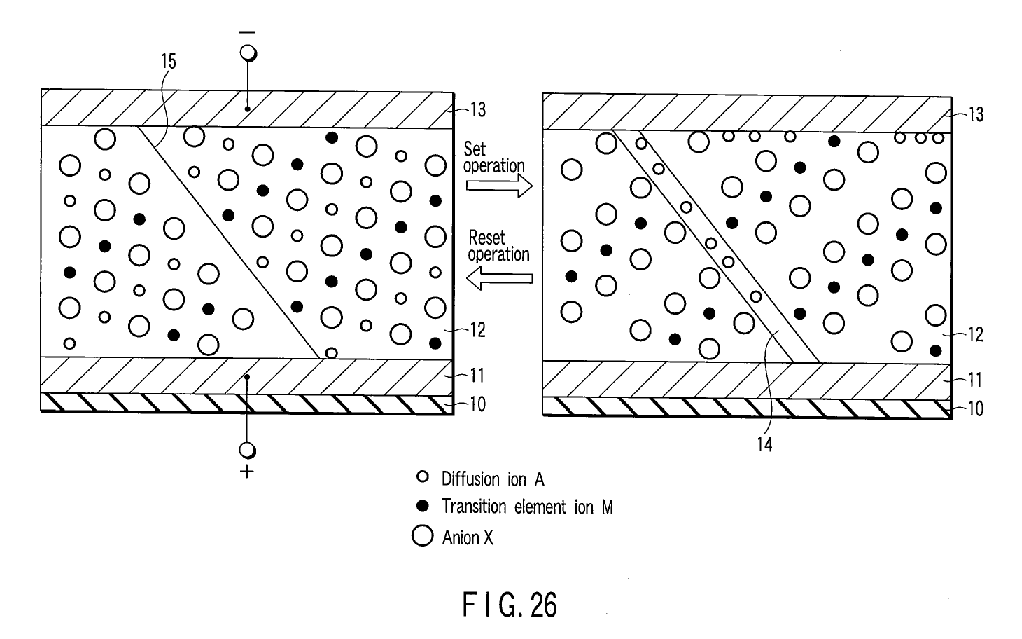

Meanwhile, in FIG. 1, described is the case in which a sufficiently large crystal is obtained. However, as shown in FIG. 26, even in the case where the crystal has an arrangement severed in the film thickness direction, movement of the X ions and the accompanying resistance change can be generated by the mechanism described in the present invention.

That is, when adding a negative voltage to the electrode layer 13 with the electrode layer 11 earthed, a potential gradient is generated inside the recording layer 12, and thus the diffusion ions Cu are transported. When the diffusion ions Cu move to a crystal interface, the diffusion ions Cu receive the electrons gradually from the region close to the electrode layer 13, and behave like a metal. As a result, a metal layer 14 is formed in the vicinity of the crystal interface.

Further, in the recording layer 12, the valence of the X ions increases, and accordingly its conductivity increases. In such a case, since a conductive path of the metal layer 14 is formed along the crystal interface, the resistance between the electrode layer 11 and the electrode layer 13 decreases, so that the recording element changes to a low resistance condition.

Also in this case, it is possible to return to a high resistance condition by pulling the diffusion ions Cu at the crystal interface back into the original crystal structure by Joule heating based on a large-current pulse, or applying the voltage pulse of the inverse direction.

However, in order to effect movement of the diffusion ions Cu efficiently, as shown in FIG. 1, the direction in which the diffusion ions Cu diffuse and the direction in which an electric field is applied are preferably the same.

### EMBODIMENTS

Next, explanation will be made about some embodiments believed to be the best.

Hereinafter, explanation will be made about two cases, i.e. the first case in which the example of the present invention is applied to the probe memory and the second case in which it is applied to the semiconductor memory.

(1) Probe Memory

A. Structure

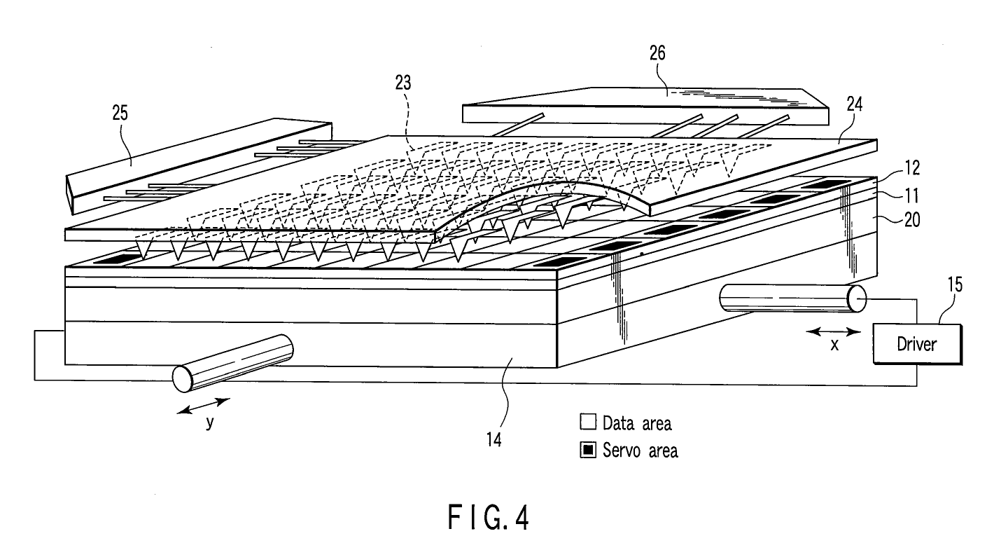

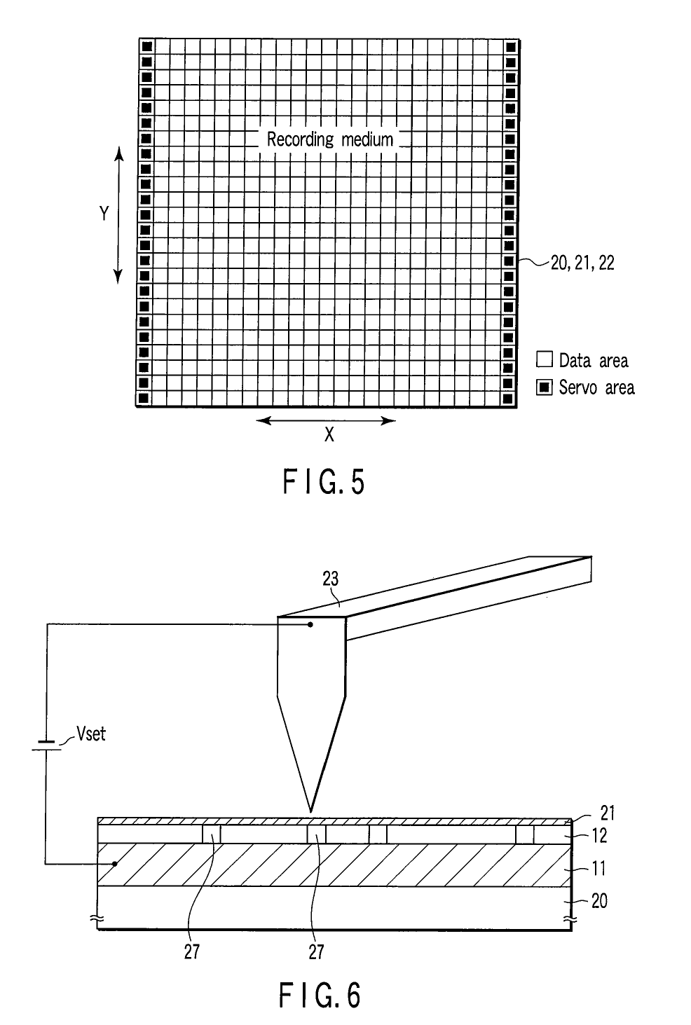

FIGS. 4 and 5 show a probe memory according to an example of the invention.

An electrode layer 11 is disposed on a semiconductor substrate 20, and a recording layer 12 having data areas and servo areas is disposed on the electrode layer 11. The recording layer 12 is comprised, for instance, a recording medium (recording part) having the structure as shown in FIG. 1. The recording medium is formed flat at a center part of the semiconductor substrate 20.

The servo area is disposed along an edge of the semiconductor substrate 20. The data area and the servo area are comprised a plurality of blocks. Probes 23 corresponding to the blocks are disposed on the data area and the servo area. Each of the probes 23 has a pointed shape.

The probes 23 constituting a probe array are formed at one face side of the semiconductor substrate 24. The probes 23 are formed easily at one face side of the semiconductor substrate 24 by utilizing MEMS technology.

The position of the probe 23 on the data area is controlled by a servo burst signal read out from the servo area. Specifically, an access operation is executed by performing positional control of the probes 23 in the Y direction while causing the semiconductor substrate 20 to perform a reciprocating operation in the X direction by a driver 15.

The recording medium may be formed independently in every block, the recording medium may have a structure of a circular shape as a hard disk to rotate, and each of the probes 23 moves in a radius direction of the recording medium, for instance, in the X direction.

The probes 23 have the function as the recording/erase head and the function as the reproducing head. Multiplex drivers 25, 26 supply a predetermined voltage to the probes 23 at the time of the recording, reproduction and erase.

B. Recording/Reproducing Operation

Explanation will be made about a recording/reproducing operation of the probe memory of FIGS. 4 and 5.

FIG. 6 shows the recording operation (set operation).

The recording medium is comprised an electrode layer 11 on a semiconductor chip 20, a recording layer 12 and a protection layer 21. The protection layer 21 is comprised a resistive element. The resistance value of the protection layer 21 is preferably larger than the minimum resistance value and smaller than the maximum resistance value of a recording unit 27.

Information recording is performed in such a way that a pointed end of the probe 23 is caused to come into contact with a surface of the protection layer 21, a voltage is applied to the recording unit 27 of the recording layer (recording medium) 12, and a potential gradient is generated inside the recording unit 27 of the recording layer 12. In the present example, prepared is a condition where the electric potential of the probe 23 is relatively lower than the electric potential of the electrode layer 11. A negative potential may be supplied to the probe 23 provided that the electrode layer 11 has a fixed potential (for instance, ground potential).

The voltage pulse can be generated and applied by emitting electrons toward the electrode layer 11 from the probe 23 by using, for instance, an electron generating source or hot electron source.

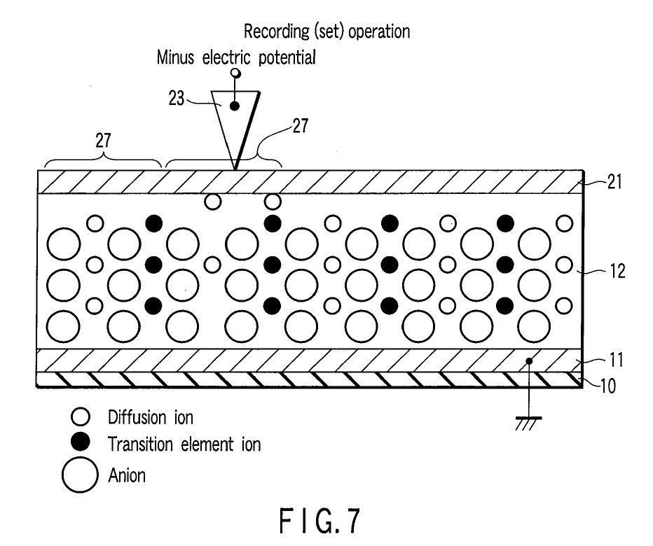

At this time, for instance, as shown in FIG. 7, in the recording unit 27 of the recording layer 12, part of the diffusion ions moves to the probe (cathode) 23 side, the diffusion ions inside the crystal relatively decreases to the anions. Further, the diffusion ions moved to the probe 23 side separate out as a metal, while receiving electrons from the probe 23.

In the recording unit 27 of the recording layer 12, the anions become excessive. As a result, the valence of transition element ions remaining inside the recording layer 12 is caused to increase. That is, the recording unit 27 of the recording layer 12 comes to have electron conductivity based on implantation of carriers by phase change, which completes the information recording (set operation).

The voltage pulse for the information recording can also be generated by preparing the condition where the electric potential of the probe 23 is relatively higher than the electric potential of the electrode layer 11.

According to the probe memory of the present example, as in a hard disk, it is possible to perform information recording to the recording unit 27 of the recording medium, and by adopting a new recording material, it is possible to realize a higher recording density than the conventional hard disk or semiconductor memory.

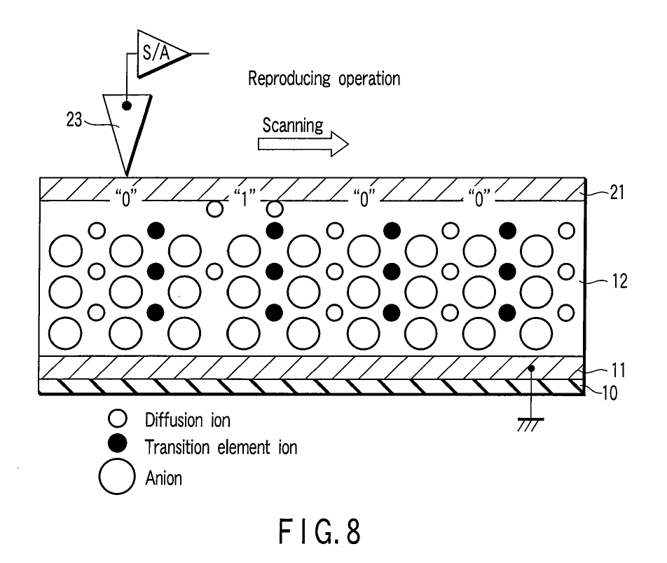

FIG. 8 shows the reproducing operation.

A reproducing operation is performed by detecting the resistance value of the recording unit 27 of the recording layer 12 by causing the voltage pulse to flow through the recording unit 27 of the recording layer 12. In this case, the voltage pulse is made to be a minute value to the degree that the material constituting the recording unit 27 of the recording layer 12 does not cause the phase change.

For instance, a read current generated by a sense amplifier S/A is caused to flow through the recording unit 27 of the recording layer (recording medium) 12 from the probe 23, and then, the resistance value of the recording unit 27 is measured by the sense amplifier S/A. If the new material explained already is used, it is possible to secure a ratio of difference in the resistance value between the high and low resistance conditions of 10³ or more.

In the reproducing operation, continuous reproduction becomes possible by scanning the recording medium by the probe 23.

An erase (reset) operation is performed by promoting the oxidation reduction reaction in the recording unit 27 of the recording layer 12 while performing joule heating of the recording unit 27 of the recording layer 12 based on the large-current pulse. Alternatively, it is also possible to perform an erase operation by applying the voltage pulse in a direction inverse to the voltage pulse at the time of the set operation, to the recording layer 12.

The erase operation can be performed in every recording unit 27, and also can be performed on a plurality of recording units 27 or on a block unit.

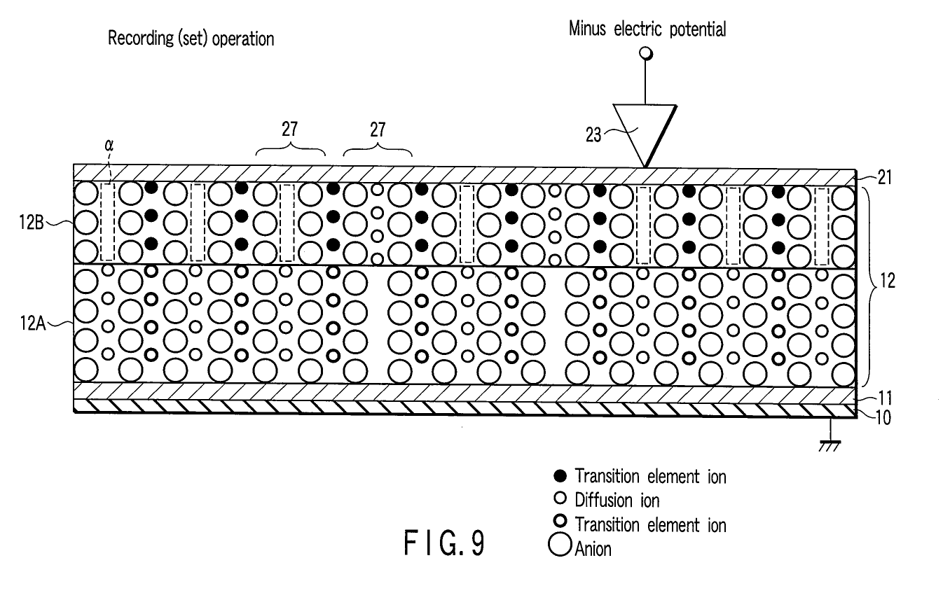

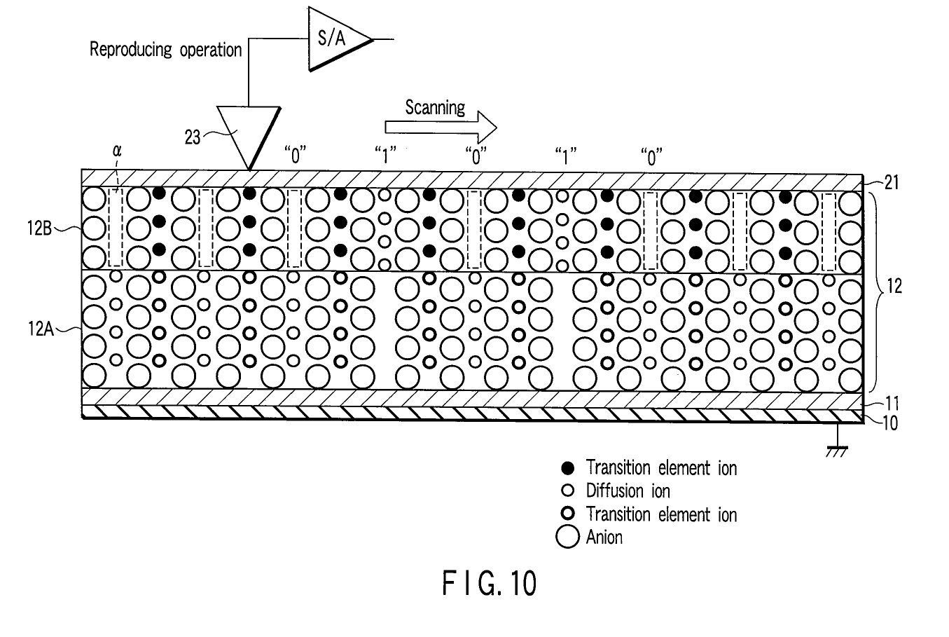

Meanwhile, FIG. 9 shows the recording operation for the structure of FIG. 2, and FIG. 10 shows the reproducing operation for the structure of FIG. 2.

C. Summary

According to such probe memory, it is possible to realize a higher recording density and lower power consumption than those of the present hard disk or flash memory.

(2) Semiconductor Memory

A. Structure

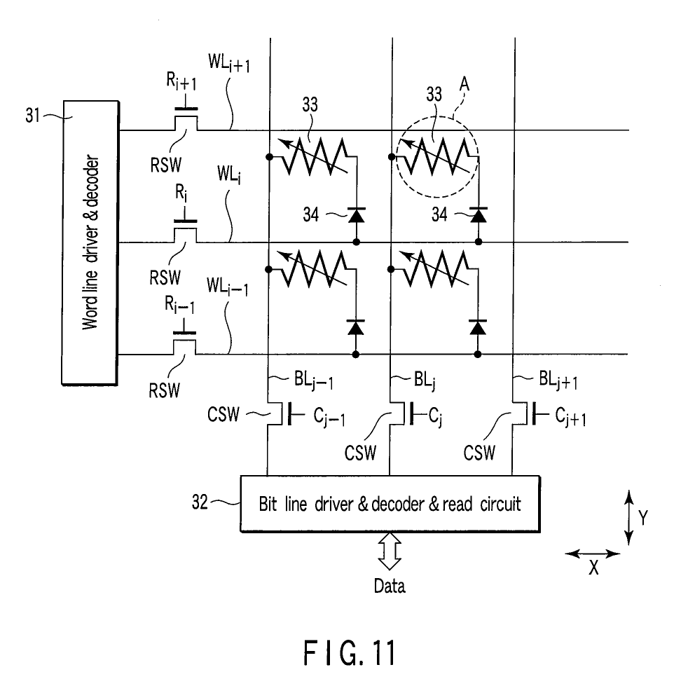

FIG. 11 shows a cross point type semiconductor memory according to an example of the invention.

Word lines WLi−1, WLi, and WLi+1 extend in the X direction, and bit lines BLj−1, BLj, and BLj+1 extend in the Y direction.

Each one end of the word lines WLi−1, WLi, and WLi+1 is connected to a word line driver & decoder 31 via a MOS transistor RSW as a selection switch, and each one end of the bit lines BLj−1, BLj, and BLj+1 is connected to a bit line driver & decoder & read circuit 32 via a MOS transistor CSW as a selection switch.

Selection signals Ri−1, Ri, and Ri+1 for selecting one word line (row) are input to a gate of the MOS transistor RSW, and selection signals Ci−1, Ci, and Ci+1 for selecting one bit line (column) are input to a gate of the MOS transistor CSW.

A memory cell 33 is disposed at each intersection part of the word lines WLi−1, WLi, and WLi+1 and the bit lines BLj−1, BLj, and BLj+1. This is a so-called cross point type cell array structure.

A diode 34 is added to the memory cell 33 for preventing a sneak current from flowing through the memory cell 33 at the time of recording/reproduction.

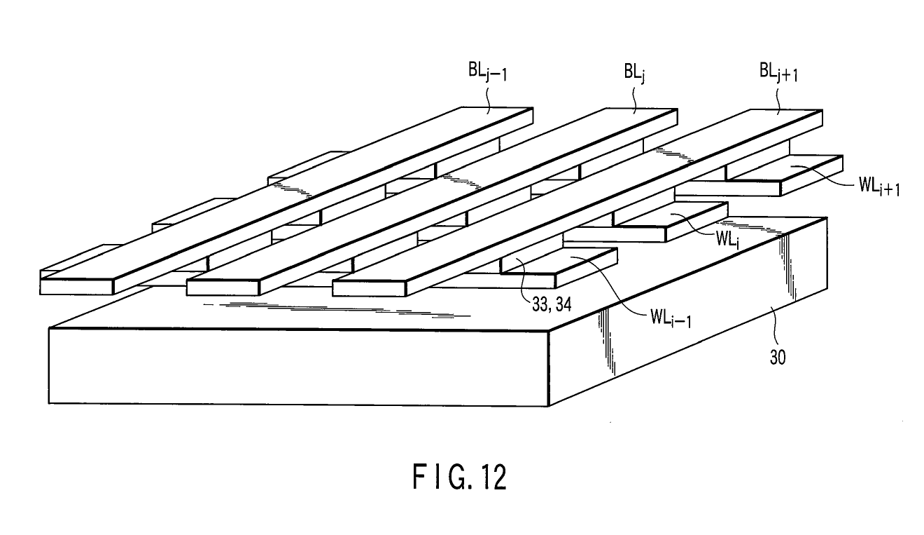

FIG. 12 shows a structure of the memory cell array part of the semiconductor memory of FIG. 11.

The word lines WLi−1, WLi, and WLi+1 and the bit lines BLj−1, BLj, and BLj+1 are disposed on a semiconductor chip 30, and the memory cells 33 and the diodes 34 are disposed at the intersection parts of these wirings.

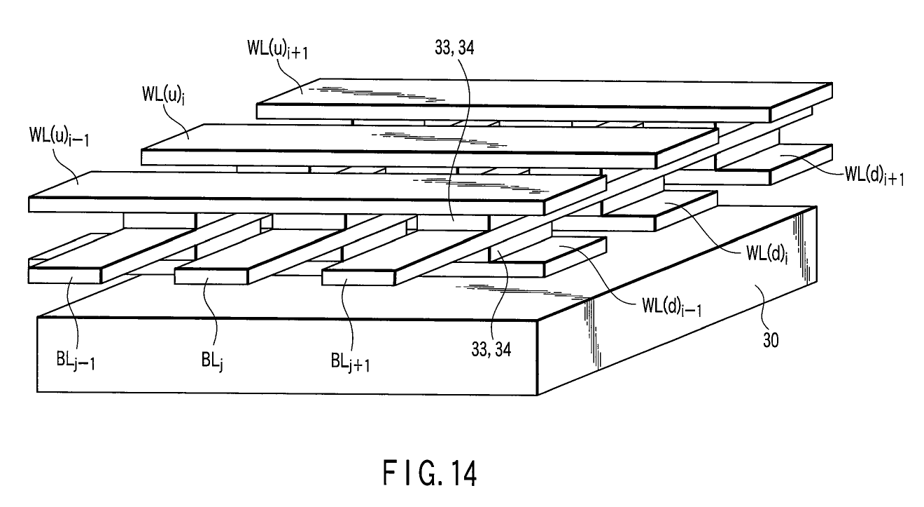

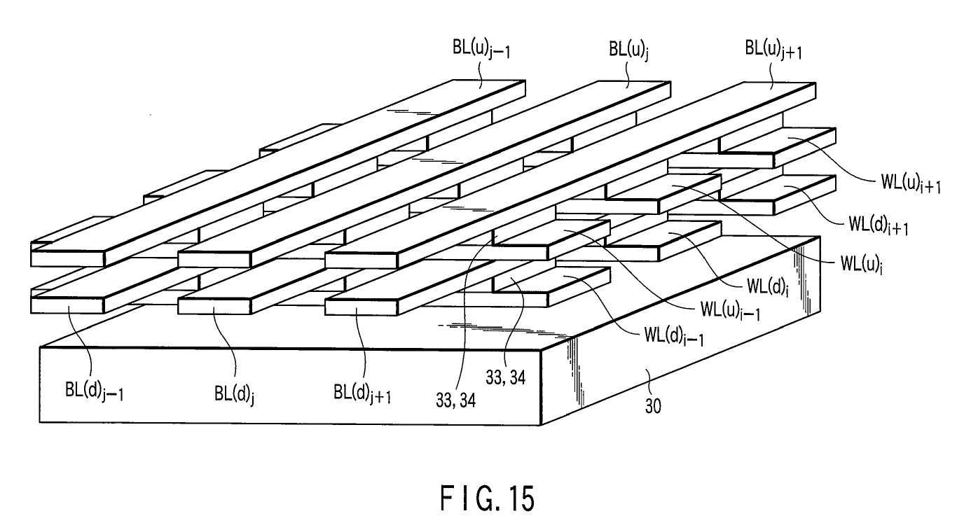

One feature of such cross point type cell array structure lies in a point that, since it is not necessary to connect the MOS transistor individually to the memory cell 33, a higher integration can be realized. For instance, as shown in FIGS. 14 and 15, it is possible to give the memory cell array a three-dimensional structure, by stacking the memory cells 33.

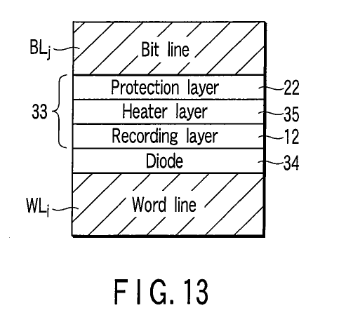

The memory cell 33, for instance, is comprised a stack structure of the recording layer 12, the protection layer 22 and a heater layer 35 as shown in FIG. 13. One bit data is stored in one memory cell 33. Further, the diode 34 is disposed between the word line WLi and the memory cell 33.

B. Recording/Reproducing Operation

A recording/reproducing operation will be explained using FIGS. 11 to 13.

Here, it is assumed that the memory cell 33 surrounded by dotted line A is selected, and the recording/reproducing operation is executed with respect to the memory cell 33.

Information recording (set operation) may be performed by causing current pulses to flow through the selected memory cell 33 by generating a potential gradient inside the memory cell 33, after applying the voltage to the selected memory cell 33. Therefore, for instance, prepared is a condition where the electric potential of the word line WLi becomes relatively lower than the electric potential of the bit line BLj. A negative potential may be supplied to the word line WLi when the bit line BLj has the fixed potential (for instance, ground potential).

At this time, in the selected memory cell 33 surrounded by the dotted line A, part of the diffusion ions moves to the word line (cathode) WLi side, and accordingly, the diffusion ions inside the crystal decrease relatively to the anions. Further, the diffusion ions having moved to the word line WLi side separate out as a metal while receiving the electrons from the word line WLi.

In the selected memory cell 33 surrounded by the dotted line A, the anions become excessive. As a result, the valence of the transition element ions inside the crystal is caused to increase. That is, the selected memory cell 33 surrounded by the dotted line A comes to have electron conductivity due to implantation of carriers caused by phase change, which thus completes the information recording (set operation).

Meanwhile, at the time of the information recording, non-selected word lines WLi−1, WLi+1, and non-selected bit lines BLj−1, BLj+1 are all preferably biased into the same electric potential.

Further, at the time of standby before the information recording, it is preferable for all the word lines WLi−1, WLi, and WLi+1, and all the bit lines BLj−1, BLj, and BLj+1, to be pre-charged.

Furthermore, the current pulse for the information recording may be generated by preparing the condition where the electric potential of the word line WLi is relatively higher than the electric potential of the bit line BLj.

Information reproduction is performed by detecting a resistance value of the memory cell 33 after causing the current pulse to flow through the selected memory cell 33 surrounded by the dotted line A. However, it is necessary for the current pulse to be a minute value to the degree that the material constituting the memory cell 33 does not cause the phase change.

For instance, the read current (current pulse) generated by a read circuit is caused to flow through the memory cell 33 surrounded by the dotted line A from the bit line BLj, and then, the resistance value of the memory cell 33 is measured by the read circuit. If adopting the new material described already, a difference in the resistance value between the set and reset conditions of 10³ or more can be secured.

An erase (reset) operation is performed by facilitating the oxidation-reduction reaction in the memory cell 33 while performing joule heating of the selected memory cell 33 surrounded by the dotted line A based on the large-current pulse.

Here, when the interior of the recording layer 22 formed at the intersection part of the word line WLi and the bit line BLj is in a polycrystalline condition or a monocrystalline condition, movement of the diffusion ions inside the crystal is easy to be generated, which is preferable. However, even in this case, when the size of the crystal grains differs largely at respective intersection parts, there is a possibility that characteristics of the recording layer in the respective intersection parts vary. Therefore, it is preferable, in the respective intersection parts, for the size of the crystal grains to be approximately uniform, and for the distribution thereof to preferably follow a distribution having a single peak. In this case, the size of the crystal grain severed at the interface of respective intersection parts is not taken into consideration at the time the distribution is obtained. In order to utilize the movement of the diffusion ions inside the crystal structure, the size of the crystal grains is preferably of the same degree as the film thickness or more, and therefore, the number of crystal grains included in the respective intersection parts is preferably 10 or less. Further, it is more preferable that the number of crystal grains is 4 or less.

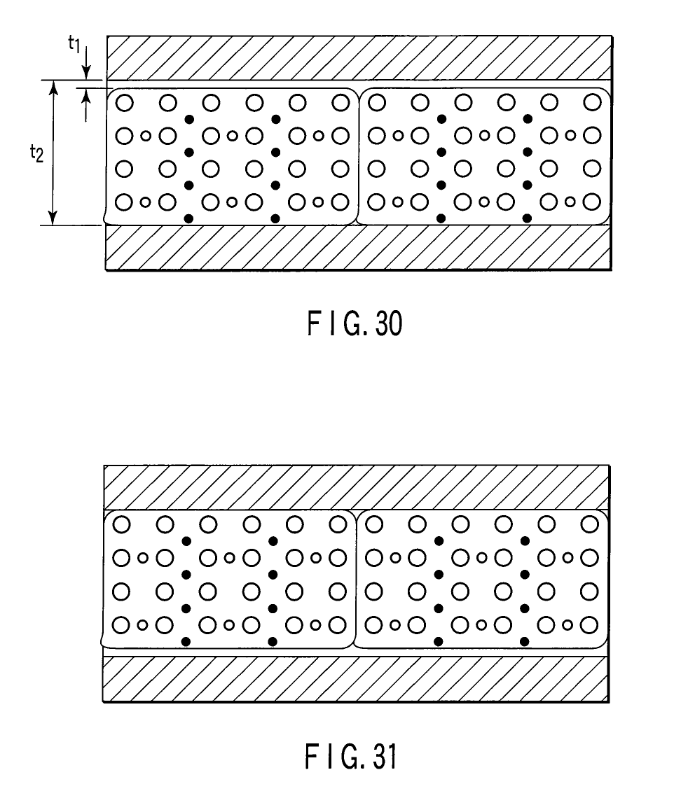

Explanation will now be made using FIGS. 30 and 31 regarding the fact that, when layering no second chemical compound, the recording layer may have a minimal amorphous part at an upper part or lower part of the crystal part of the first chemical compound.

As described using FIG. 1, A ions separate out as A metal inside the recording layer, after being diffused via the moving path. At this time, when the A ions diffuse to the end part of crystal grain of the first chemical compound, followed by separating out at interface part of the first chemical compound being in the amorphous condition, it is preferable since there is an air gap to be occupied by the A ions. However, when film thickness t1 of the layer being in the amorphous condition becomes excessively thick, the recording layer as a whole does not cause the resistance change effectively. Explanation will next be made about a preferable range of t1 for the overall film thickness t2 of the recording layer.

Generally, the resistance of the amorphous part takes a value between where the first chemical compound is in the insulating condition and where the first chemical compound is in the conductive condition. Since the resistance change of the amorphous layer based on movement of the A ions is not large, in order that the resistance change of the recording film is made to the degree of one significant figure, it is preferable for the film thickness t1 of the amorphous layer to be 1/10 or less of t2.

The amorphous layer may exist on either the upper part of the first chemical compound or lower part thereof. However, in order to orient the first chemical compound in a required direction, generally, orientation control is performed by using a lower layer which agrees with the first chemical compound in lattice constant. Therefore, it is preferable for the amorphous part to exist on the upper part of the first chemical compound.

Further, the amorphous layer may be generated at the time a next layer contacting the recording layer is formed. In such a case, the composition of the amorphous layer, unlike the composition of the first chemical compound, includes part of the materials of the next layer contacting the recording layer, and thus the amorphous layer produces an effect that the adhesion property between the recording film material and the next layer is heightened. In this case, film thickness t1 of the amorphous layer becomes 10 nm or less. It is more preferable for t1 to be 3 nm or less.

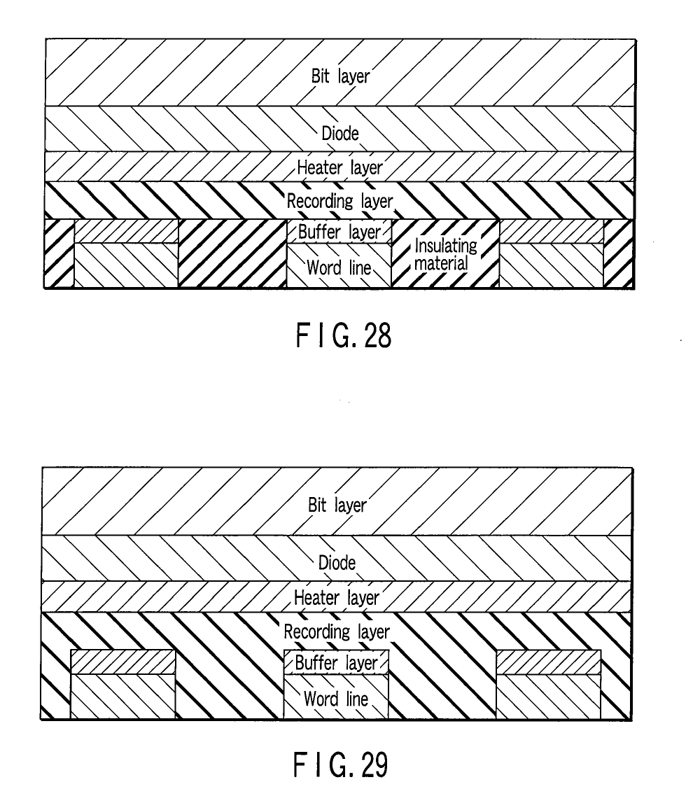

Likewise, there is next considered the interface of respective interconnection parts. When the recording layer is subjected to a process in which the recording layer is fabricated in the same shape as the word line after forming the recording layer uniformly, there is a possibility that the characteristic of the fabricated face of the recording layer is different from the characteristic of the interior of the crystal. As a method for avoiding this influence, there is a method in which a uniform recording layer is used without fabricating the layer, by using the recording layer that becomes the insulator at the time of film formation. In this case, as shown in FIG. 28, in the case where the space between the word lines is embedded with materials having an insulating property, the recording layer may be formed on the word lines and the insulator. Alternatively, in the case where the recording film material functions as an insulator of the space between the word lines, as shown in FIG. 29, the recording layer may be formed on the word line and on the substrate. Thus, it is possible to form arbitrary films before forming the film of the recording layer, and in FIG. 28, there is exemplified a case in which a buffer layer is formed evenly to suppress diffusion of the recording layer material before forming the recording layer. In FIGS. 28 and 29, the case where the recording film is uniform is shown. However, in the case where the recording layer is processed only in the direction of the bit line or the word line, or the recording layer is processed more than the respective intersection points, it is possible to similarly disregard the influence of the fabricated face.

C. Summary

According to such a semiconductor memory, a higher recording density and lower power consumption than those of the existing hard disk or flash memory can be realized.

(3) Others

In the present embodiment, explanation is made about the probe memory and the semiconductor memory. However, it is possible to apply the material and principle proposed in the example of the present invention to the recording medium such as the existing hard disk or DVD.

Application for Flash Memory

(1) Structure

It is also possible for the example of the present invention to be applied to the flash memory.

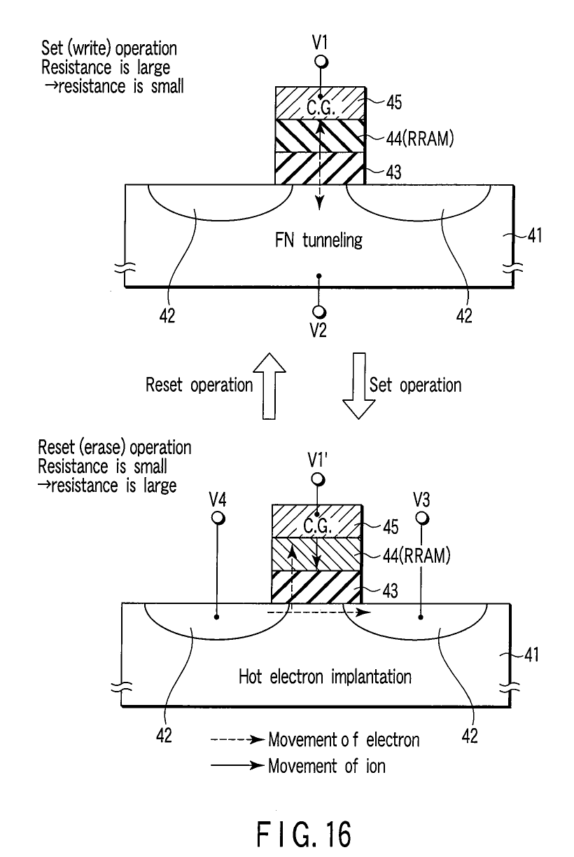

FIG. 16 shows a memory cell of the flash memory.

The memory cell of the flash memory is comprised a MIS (metal-insulator-semiconductor) transistor.

In a surface region of a semiconductor substrate 41, a diffusion layer 42 is formed. A gate insulating layer 43 is formed on a channel region between the diffusion layers 42. A recording layer (RRAM: Resistive RAM) 44 according to an example of the present invention is formed on the gate insulating layer 43. A control gate electrode 45 is formed on the recording layer 44.

The semiconductor substrate 41 may be a well region, and the semiconductor substrate 41 and the diffusion layer 42 have reverse conductivity types mutually. The control gate electrode 45 serves as the word line and is comprised conductive polysilicon.

The recording layer 44 is comprised the materials shown in FIG. 1, 2 or 3.

(2) Fundamental Operation

Explanation will be next made about fundamental operation using FIG. 16.

A set (write) operation is executed by supplying an electric potential V1 to the control gate electrode 45, and supplying an electric potential V2 to the semiconductor substrate 41.

The difference between the electric potentials V1, V2 needs to be sufficiently large for the recording layer 44 to cause a phase change or a resistance change. However, its direction is not limited particularly.

That is, either case of V1>V2 or V1<V2 may be applied.

For instance, in an initial condition (reset condition), it is assumed that the recording layer 44 is an insulator (resistance is large). In this case, since the gate insulating layer 43 becomes quite thick, a threshold of the memory cell (MIS transistor) becomes high.

When the recording layer 44 is changed into a conductor (resistance is small) while supplying the electric potentials V1, V2 from this condition, the gate insulating layer 43 practically becomes quite thin. As a result, a threshold of the memory cell (MIS transistor) becomes low.

Meanwhile, the electric potential V2 is supplied to the semiconductor substrate 41, but instead the electric potential V2 may be transferred to the channel region of the memory cell from the diffusion layer 42.

A reset (erase) operation is executed in such a way that an electric potential V1′ is supplied to the control gate electrode 45, an electric potential V3 is supplied to one of the diffusion layers 42, and an electric potential V4 (<V3) is supplied to the other of the diffusion layers 42.

The electric potential V1′ is made a value exceeding the threshold of the memory cell being in the set condition.

At this time, the memory cell becomes ON, the electrons flow in one direction from the other direction of the diffusion layer 42, and hot electrons are generated. Since the hot electrons are implanted into the recording layer 44 via the gate insulating layer 43, the temperature of the recording layer 44 increases.

Herewith, since the recording layer 44 changes to the insulator (resistance is large) from the conductor (resistance is small), the gate insulating layer 43 practically becomes thick. Accordingly, the threshold of the memory cell (MIS transistor) becomes high.

In this manner, since, by using similar principle to the flash memory, the threshold of the memory cell can be changed, it is possible to put the information recording/reproducing device according to the example of the present invention to practical use, while utilizing the technique of flash memory.

(3) NAND Type Flash Memory

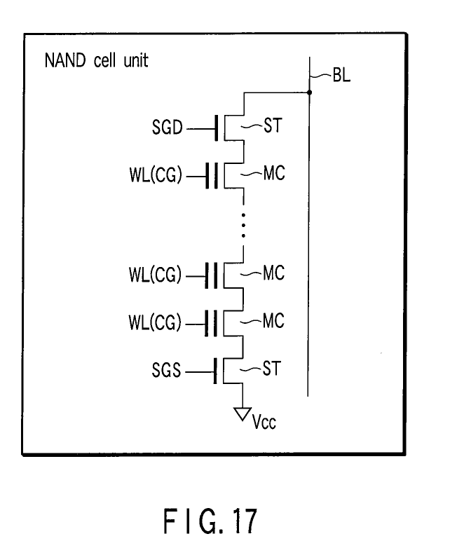

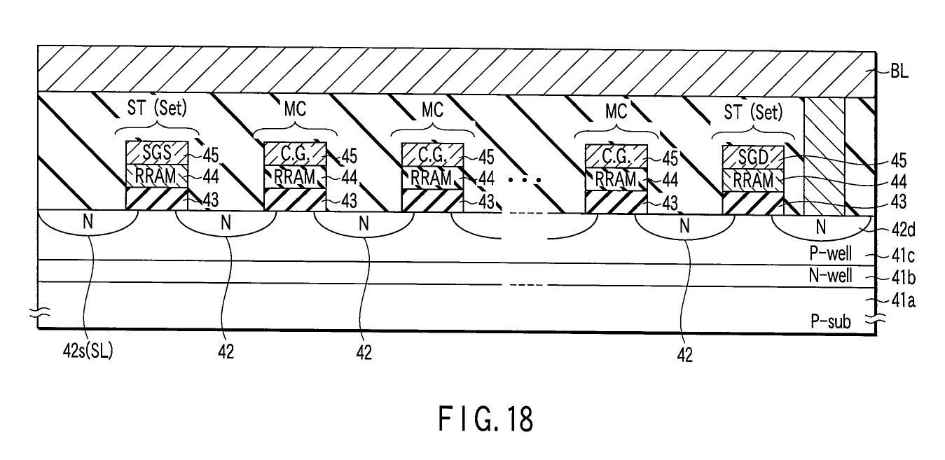

FIG. 17 shows a circuit diagram of a NAND cell unit. FIG. 18 shows a structure of the NAND cell unit according to the example.

An N type well region 41b and a P type well region 41c are formed inside a P type semiconductor substrate 41a. The NAND cell unit according to the example of the present invention is formed inside the P type well region 41c.

The NAND cell unit is comprised a NAND string comprised a plurality of memory cells MC connected in series, and a total of two select gate transistors ST connected to the both ends of the NAND string one by one.

The structure of the memory cell MC is the same as that of the select gate transistor ST. Specifically, these are comprised an N type diffusion layer 42, a gate insulating layer 43 on the channel region between the N type diffusion layers 42, a recording layer (RRAM) 44 on the gate insulating layer 43, and a control gate electrode 45 on the recording layer 44.

Conditions (insulator/conductor) of the recording layer 44 of the memory cell MC can be changed by the above-described fundamental operation. On the other hand, the recording layer 44 of the select gate transistor ST is fixed to the set condition, that is, the conductor (resistance is small).

One of the select gate transistors ST is connected to a source line SL, and the other one is connected to a bit line BL.

It is assumed that, before the set (write) operation, all memory cells inside the NAND cell unit are in the reset condition (resistance is large).

The set (write) operation is sequentially performed one by one toward the memory cell at the bit line BL side from the memory cell MC at the source line SL side.

V1 (plus potential) as the write potential is supplied to the selected word line (control gate electrode) WL, and Vₚₐₛₛ as a transfer potential (electric potential by which memory cell MC becomes ON) is supplied to the non-selected word line WL.

Program data is transferred to the channel region of the selected memory cell MC from the bit line BL, while turning the select gate transistor ST at the source line SL side OFF, and turning the select gate transistor ST at the bit line BL side ON.

For instance, when the program data is “1”, a write inhibit potential (for instance, electric potential being the same degree as V1) is transferred to the channel region of the selected memory cell MC, so that the resistance value of the recording layer 44 of the selected memory cell MC does not change into low condition from high condition.

When the program data is “0”, the resistance value of the recording layer 44 of the selected memory cell MC is changed into the low condition from the high condition, by transferring V2 (<V1) to the channel region of the selected memory cell MC.

In the reset (erase) operation, for instance, V1′ is supplied to all the word lines (control gate electrode) WL to make all the memory cells MC inside the NAND cell unit ON. Further, two select gate transistors ST are turned ON, V3 is supplied to the bit line BL, and V4 (<V3) is supplied to the source line SL.

At this time, since the hot electrons are implanted to the recording layer 44 of all the memory cells MC inside the NAND cell unit, the reset operation is collectively executed for all the memory cells MC inside the NAND cell unit.

The read operation is performed in such a way that a read potential (plus potential) is supplied to the selected word line (control gate electrode) WL, and electric potentials by which the memory cell MC becomes inevitably ON regardless of whether data “0” or “1” is supplied to the non-selected word line (control gate electrode) WL.

Further, the two select gate transistors ST are turned ON, and the read current is supplied to the NAND string.

Since the selected memory cell MC, when applied with the read potential, becomes ON or OFF in accordance with the data value stored therein, for instance, it is possible to read the data by detecting changes of the read current.

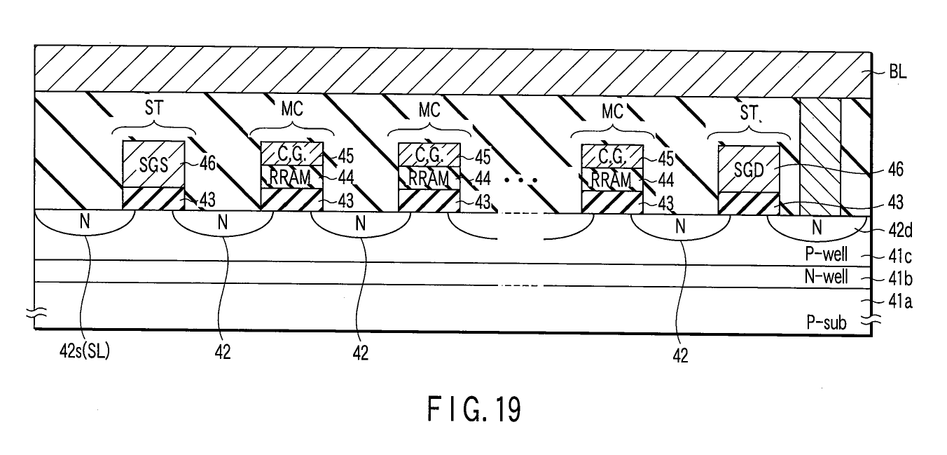

Meanwhile, in the structure of FIG. 18, the select gate transistor ST has the same structure as the memory cell MC. However, for instance, as shown in FIG. 19, the select gate transistor ST may be a normal MIS transistor without forming the recording layer.

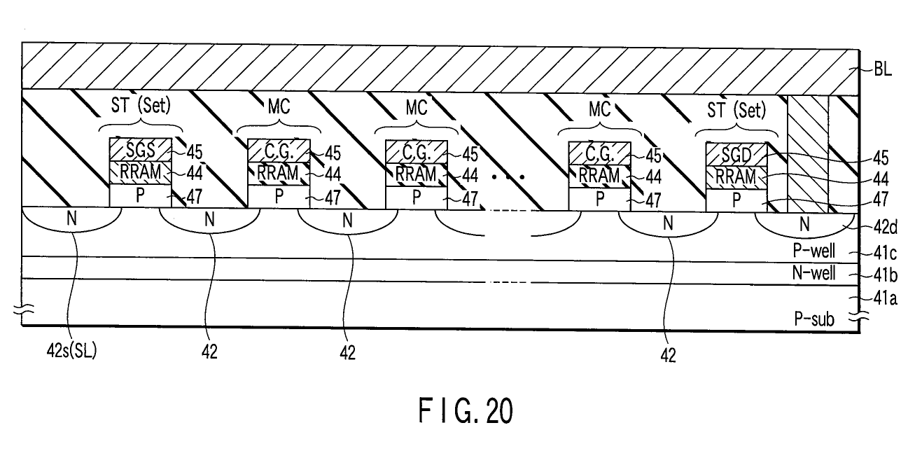

FIG. 20 shows a modified example of the NAND type flash memory.

The modified example has a characteristic in that the gate insulating layer of a plurality of memory cells MC constituting the NAND string is replaced with a P type semiconductor layer 47.

When high integration is advanced and the memory cell MC is miniaturized, with the condition where the voltage is not supplied, the P type semiconductor layer 47 is filled with a depletion layer.

At the time of set (write), a plus write potential (for instance, 3.5 V) is supplied to the control gate electrode 45 of the selected memory cell MC, and a plus transfer potential (for instance, 1V) is supplied to the control gate electrode 45 of the non-selected memory cell MC.

At this time, a surface of the P type well region 41c of a plurality of memory cells MC inside the NAND string inverts from P type to N type, so that a channel is formed.

Consequently, as described above, the set operation can be performed in such a way that the select gate transistor ST at the bit line BL side is turned ON, and the program data “0” is transferred to the channel region of the selected memory cell MC from the bit line BL.

A reset (erase) can be performed collectively for all the memory cells MC constituting the NAND string in such a way that, for instance, a minus erase potential (for instance, −3.5 V) is supplied to all the control gate electrodes 45, and the ground potential (0 V) is supplied to the P type well region 41c and the P type semiconductor layer 47.

At the time of read, the plus read potential (for instance, 0.5 V) is supplied to the control gate electrode 45 of the selected memory cell MC, and the transfer potential (for instance, 1 V) by which the memory cell MC becomes inevitably ON regardless of the data “0”, “1” is supplied to the control gate electrode 45 of the non-selected memory cell MC.

It is assumed that, the threshold voltage Vth “1” of the memory cell MC in the “1” condition should fall in the range of 0 V<Vth “1”<0.5 V, and the threshold voltage Vth “0” of the memory cell MC in the “0” condition should fall in the range of 0.5 V<Vth “0”<1 V.

Further, the read current is supplied to the NAND string while turning the two select gate transistors ST ON.

If such condition is prepared, the current quantity flowing through the NAND string is changed in accordance with the data value stored in the selected memory cell MC. Therefore, the data can be read by detecting this change.

Meanwhile, in this modified example, it is preferable that the hole doping amount of the P type semiconductor layer 47 is more than that of the P type well region 41c, and the Fermi level of the P type semiconductor layer 47 is deeper than that of the P type well region 41c by about 0.5 V.

This is performed in order that, when a plus potential is supplied to the control gate electrode 45, inversion from P type to N type commences from the surface part of the P type well region 41c between the N type diffusion layers 42, so that the channel is to be formed.

Accordingly, for instance, at the time of write, the channel of the non-selected memory cell MC is formed only at an interface between the P type well region 41c and the P type semiconductor layer 47; and at the time of read, the channel of a plurality of memory cells MC inside the NAND string is formed only at an interface between the P type well region 41c and the P type semiconductor layer 47.

That is, even though the recording layer 44 of the memory cell MC is in the conductor condition (set condition), the diffusion layer 42 and the control gate electrode 45 do not short-circuit.

(4) NOR Type Flash Memory

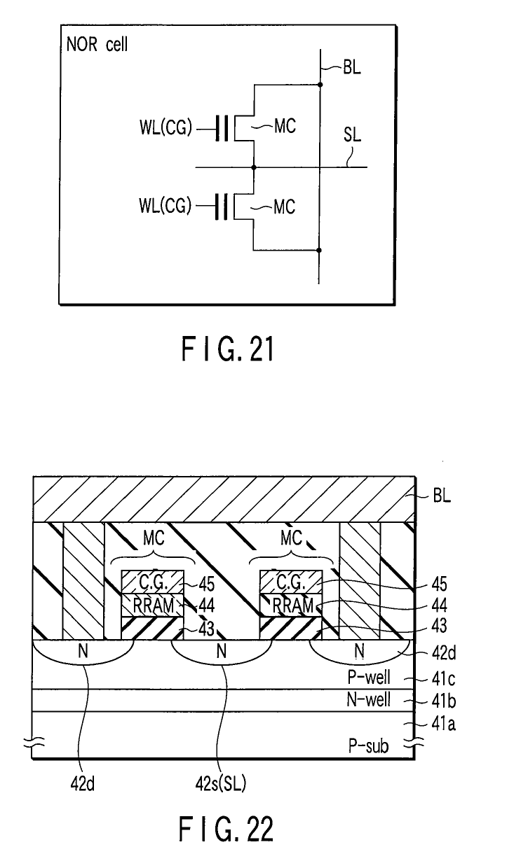

FIG. 21 shows a circuit diagram of a NOR cell unit. FIG. 22 shows the structure of the NOR cell unit according to an example.

An N type well region 41b and a P type well region 41c are formed inside a P type semiconductor substrate 41a. The NOR cell according to the example of the present invention is formed inside the P type well region 41c.

The NOR cell is comprised one memory cell (MIS transistor) MC connected between the bit line BL and the source line SL.

The memory cell MC is comprised an N type diffusion layer 42, a gate insulating layer 43 on the channel region between the N type diffusion layers 42, a recording layer (RRAM) 44 on the gate insulating layer 43, and a control gate electrode 45 on the recording layer 44.

The conditions (insulator/conductor) of the recording layer 44 of the memory cell MC can be changed by the above-described fundamental operation.

(5) 2-Transistor Type Flash Memory

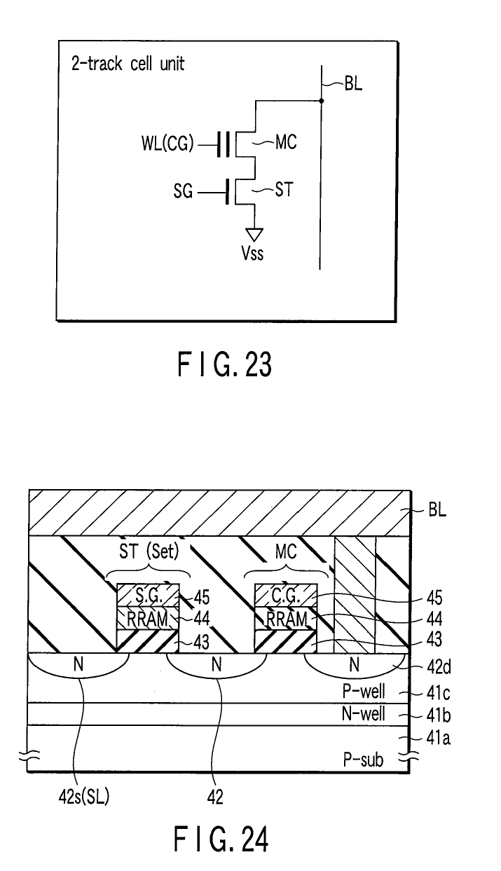

FIG. 23 shows a circuit diagram of a 2-transistor cell unit. FIG. 24 shows the structure of the 2-transistor cell unit according to the example of the invention.

The 2-transistor cell unit is developed lately as a new cell structure having the characteristic of the NAND cell unit in conjunction with the characteristic of the NOR cell.

An N type well region 41b and a P type well region 41c are formed inside a P type semiconductor substrate 41a. The 2-transistor cell unit according to the example of the present invention is formed inside the P type well region 41c.

The 2-transistor cell unit is comprised one memory cell MC and one select gate transistor ST connected in series.

The structure of the memory cell MC is the same as that of the select gate transistor ST. Specifically, these are comprised an N type diffusion layer 42, a gate insulating layer 43 on the channel region between the N type diffusion layers 42, a recording layer (RRAM) 44 on the gate insulating layer 43, and a control gate electrode 45 on the recording layer 44.

The condition (insulator/conductor) of the recording layer 44 of the memory cell MC can be changed by the above-described fundamental operation. On the other hand, the recording layer 44 of the select gate transistor ST is fixed in the set condition, that is, the conductor (resistance is small).

The select gate transistor ST is connected to the source line SL, and the memory cell MC is connected to the bit line BL.

The conditions (insulator/conductor) of the recording layer 44 of the memory cell MC can be changed by the above-described fundamental operation.

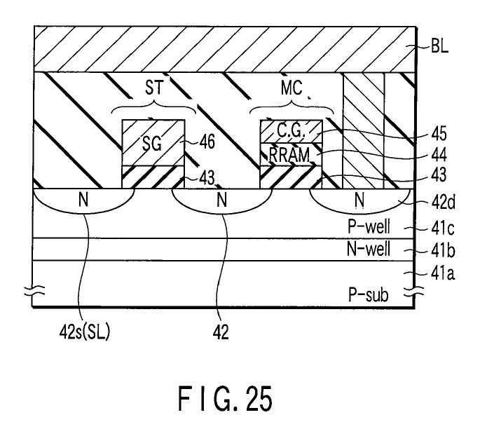

In the structure of FIG. 24, the select gate transistor ST has the same structure as the memory cell MC. However, for instance, as shown in FIG. 25, the select gate transistor ST may be a normal MIS transistor as the select gate transistor ST without forming the recording layer.

### EXPERIMENTAL EXAMPLES

Experimental examples will be explained in which some samples were prepared, and the resistance difference between the initial (erase) condition and the recording (write) condition was evaluated.

Simplified samples were adopted in which the recording part according to the examples of the present invention is formed on a disk comprised a glass substrate with a diameter of about 60 nm, and a thickness of about 1 mm.

### (1) First Experimental Example

The sample of the first experimental example is as follows:

The recording part is comprised a layer stack of an underlying layer, an electrode layer, a recording layer and a protection layer. The electrode layer is formed by layering a CeO₂ underlying layer formed with a thickness of approximately 50 nm on the disk, followed by layering a TiN film of 100 nm thereon. The recording layer is made from CuCoO₂, and the protection layer is made from diamond-like carbon (DLC).

The CuCoO₂ with a thickness of approximately 10 nm is formed on the disk, for instance, by performing RF magnetron sputtering in an ambient atmosphere of Ar 95.5%, O₂ 0.5%, while maintaining the temperature of the disk to a value in the range of 500° C. to 800° C. Further, the diamond-like carbon with a thickness of approximately 3 nm is formed on the CuCoO₂, for instance, by the CVD method.

Evaluation of the sample is performed by using a probe made from tungsten (W) with a sharpened tip diameter of 10 nm or less.

A write is performed by applying a voltage pulse of 1 V with a width of 10 nsec between the electrode layer and the probe, and an erase is performed by applying a voltage pulse of 0.2 V with a width of 100 nsec between the electrode layer and the probe, while causing the tip of the probe to come into contact with a surface of the recording part.

The resistance value of the recording layer was measured by applying a voltage pulse of 0.1 V with a width of 10 nsec between the electrode layer and the probe after each of write/erase. As a result, the resistance difference in the initial (erase) condition had a value of the 10⁷ Ω level, whereas the resistance difference in the recording (write) condition was changed into a value of the 10³ Ω level.

The ratio of the resistance values of write/erase became approximately 10⁴ Ω, and accordingly, confirmed was that a sufficient margin could be secured on the occasion of a read.

### (2) Second Experimental Example

A second experimental example uses the same sample as the first experimental example except that the recording layer was made from CuAl_{0.5}Co_{0.5}O₂. Further, the manufacturing method and evaluation method are performed in the same way as the first experimental example.

Like the first experimental example, the resistance values after write/erase were of the 10³ Ω level/10⁷ Ω level, and the resistance ratio of the both was approximately 10⁴ Ω; and confirmed was that a sufficient margin could be secured on the occasion of read.

### (3) Third Experimental Example

A third experimental example uses the same sample as the first experimental example except that the recording layer was made from Cu_{1.1}Co_{0.9}O₂. Further, the manufacturing method and evaluation method are performed in the same way as the first experimental example.

Like the first experimental example, the resistance values after write/erase were of the 10³ Ω level/10⁷ Ω level, and the resistance ratio of the both was approximately 10⁴ Ω; and confirmed was that a sufficient margin could be secured on the occasion of read.

### (4) Fourth Experimental Example

A fourth experimental example uses the same sample as the first experimental example except that the recording layer was made from CuAlO₂. Further, the manufacturing method and evaluation method are performed in the same way as the first experimental example.

Like the first experimental example, the resistance values after write/erase were of the 10³ Ω level/10⁷ Ω level, and the resistance ratio of the both was approximately 10⁴ Ω; and confirmed was that a sufficient margin could be secured on the occasion of read.

### (5) Fifth Experimental Example

A fifth experimental example uses the same sample as the first experimental example except that the recording layer was made from CuMoN₂. Further, the manufacturing method and evaluation method are performed in the same way as the first experimental example.

Like the first experimental example, the resistance values after write/erase were of the 10³ Ω level/10⁷ Ω level, and the resistance ratio of the both was approximately 10⁴ Ω; and confirmed was that a sufficient margin could be secured on the occasion of the read.

### (6) Sixth Experimental Example

A sixth experimental example uses the same sample as the first experimental example except that the electrode layer was made from LaNiO₃. Further, the manufacturing method and evaluation method are performed in the same way as the first experimental example.

Like the first experimental example, the resistance values after write/erase were of the 10³ Ω level/10⁷ Ω level, and the resistance ratio of the both was approximately 10⁴ Ω; and confirmed was that a sufficient margin could be secured on the occasion of read.

### (7) Seventh Experimental Example

A seventh experimental example uses the same sample as the first experimental example except that the underlying layer was made from Si₃N₄. Further, the manufacturing method and evaluation method are performed in the same way as the first experimental example.

Like the first experimental example, the resistance values after write/erase were of the 10³ Ω level/10⁷ Ω level, and the resistance ratio of the both was approximately 10⁴ Ω; and confirmed was that a sufficient margin could be secured on the occasion of read.

### (8) Eighth Experimental Example

An eighth experimental example uses the same sample as the first experimental example except that the recording layer was made from Cu_{1.1}Y_{0.9}O₂. Further, the manufacturing method and evaluation method are performed in the same way as the first experimental example.

Like the first experimental example, the resistance values after write/erase were of the 10³ Ω level/10⁷ Ω level, and the resistance ratio of the both was approximately 10⁴ Ω; and confirmed was that a sufficient margin could be secured on the occasion of read.

### (9) Ninth Experimental

A ninth experimental example uses the same sample as the first experimental example except that the recording layer was made from CuCrO₂. Further, the manufacturing method and evaluation method are performed in the same way as the first experimental example.

Like the first experimental example, the resistance values after write/erase were of the 10³ Ω level/10⁷ Ω level, and the resistance ratio of the both was approximately 10⁴ Ω; and confirmed was that a sufficient margin could be secured on the occasion of read.

### (10) Tenth Experimental Example

A tenth experimental example uses the same sample as the first experimental example except that the recording layer was made from CuCr_{0.5}Al_{0.5}O₂. Further, the manufacturing method and evaluation method are performed in the same way as the first experimental example.

Like the first experimental example, the resistance values after write/erase were of the 10³ Ω level/10⁷ Ω level, and the resistance ratio of the both was approximately 10⁴ Ω; and confirmed was that a sufficient margin could be secured on the occasion of read.

### (11) Eleventh Experimental Example

In the eleventh experimental example, a CeO₂ buffer layer (underlying layer) with a thickness of approximately 50 nm is formed, and then the electrode layer made from TiN with a thickness of approximately 100 nm is formed. Further, the word line is formed on the electrode layer, and a vertical diode is formed on the word line.

Furthermore, a platinum layer with a thickness of approximately 10 nm is formed on the vertical diode, CuCoO₂ as the recording layer is formed on the platinum layer, and TiO₂ having a vacant site as the second chemical compound with a thickness of approximately 10 nm is formed on the recording layer. Further, the electrode layer made from TiN with a thickness of approximately 100 nm is formed again on the second chemical compound, and after that, the bit line is formed on the electrode layer.

Then, measurement was executed in the same way as the first experimental example, except that the electric potential was applied between the word line and the bit line.

Like the first experimental example, the resistance values after write/erase were of the 10³ Ω level/10⁷ Ω level, and the resistance ratio of the both was approximately 10⁴ Ω; and confirmed was that a sufficient margin could be secured on the occasion of read.

### (12) Twelfth Experimental Example

A twelfth experimental example uses the same sample as the eleventh experimental example except that the recording layer was made from CuFeO₂. Further, the manufacturing method and evaluation method are performed in the same way as the first experimental example.

The resistance value after write was of the 10³ Ω level as compared to the resistance value in the initial condition which was of the 10⁸ Ω level, and further, the resistance value after erase was of the 10⁷ Ω level. The resistance ratio of the write/erase was 10⁴ Ω to 10⁵ Ω; and confirmed was that a sufficient margin could be secured on the occasion of read.

### (13) Thirteenth Experimental Example

A thirteenth experimental example uses the same sample as the first experimental example except that the protection layer was made from SnO₂. Further, the manufacturing method and evaluation method are performed in the same way as the first experimental example.

The resistance value after write was of the 10³ Ω level as compared to the resistance value in the initial condition which was of the 10⁷ Ω level, and further, the resistance value after erase was of the 10⁵ Ω level. The resistance ratio of write/erase was 10² Ω to 10⁵ Ω; and confirmed was that a sufficient margin could be secured on the occasion of read.

### (14) Fourteenth Experimental Example

A fourteenth experimental example uses the same sample as the first experimental example except that underlying layer was made from Tb₄O₇ and the electrode layer was made from LaNiO₃. Further, the manufacturing method and evaluation method are performed in the same way as the first experimental example.

The resistance value after write was of the 10² Ω level as compared to the resistance value in the initial condition which was of the 10⁶ Ω level, and further, the resistance value after erase was of the 10⁶ Ω level. The resistance ratio of the write/erase was approximately 10⁴ Ω; and confirmed was that a sufficient margin could be secured on the occasion of read.

### (15) Fifteenth Experimental Example

A fifteenth experimental example uses the same sample as the first experimental example except that the underlying layer was made from Ta₂O₅. Further, the manufacturing method and evaluation method are performed in the same way as the first experimental example.

The resistance value after write was of the 10³ Ω level as compared to the resistance value in the initial condition which was of the 10⁸ Ω level, and further, the resistance value after erase was of the 10⁸ Ω level. The resistance ratio of the write/erase was approximately 10⁵ Ω; and confirmed was that a sufficient margin could be secured on the occasion of read.

### (16) Sixteenth Experimental Example

A sixteenth experimental example uses the same sample as the first experimental example except that the electrode layer was made from RuO₂. Further, the manufacturing method and evaluation method are performed in the same way as the first experimental example.

The resistance value after the write was of the 10³ Ω level as compared to the resistance value in the initial condition which was of the 10⁸ Ω level, and further, the resistance value after erase was of the 10⁸ Ω level. The resistance ratio of the write/erase was approximately 10⁵ Ω; and confirmed was that a sufficient margin could be secured on the occasion of read.

(21) Summary

As explained above, in any sample of the first to sixth experimental examples, it is possible to perform the fundamental operations of write, erase and read.

Table 1 gives the verification results of the first to sixteenth experimental examples.

TABLE 1

| | | | | Recording layer | Protection layer | Resistance | Resistance |
|---|---|---|---|---|---|---|---|
| | | Underlying | Electrode | (or first chemical | (or second chemical | value after | value after |
| | Mode | layer | layer | compound) | compound) | recording Ω | erase Ω |
| Experimental | Probe memory | CeO₂ | TiN | CuCoO₂ | DLC | 1.E+03 | 1.E+07 |
| example 1 | | | | | | | |
| Experimental | Probe memory | CeO₂ | TiN | CuAl_{0.5}Co_{0.5}O₂ | DLC | 1.E+03 | 1.E+07 |
| example 2 | | | | | | | |
| Experimental | Probe memory | CeO₂ | TiN | Cu_{1.1}Co_{0.9}O₂ | DLC | 1.E+03 | 1.E+07 |
| example 3 | | | | | | | |
| Experimental | Probe memory | CeO₂ | TiN | CuAlO₂ | DLC | 1.E+03 | 1.E+07 |
| example 4 | | | | | | | |
| Experimental | Probe memory | CeO₂ | TiN | CuMoN₂ | DLC | 1.E+03 | 1.E+07 |
| example 5 | | | | | | | |
| Experimental | Probe memory | CeO₂ | LaNiO₃ | CuCoO₂ | DLC | 1.E+03 | 1.E+07 |
| example 6 | | | | | | | |
| Experimental | Probe memory | Si₃N₄ | TiN | CuCoO₂ | DLC | 1.E+03 | 1.E+07 |
| example 7 | | | | | | | |
| Experimental | Probe memory | CeO₂ | TiN | Cu_{1.1}Y_{0.9}O₂ | DLC | 1.E+03 | 1.E+07 |
| example 8 | | | | | | | |
| Experimental | Probe memory | CeO₂ | TiN | CuCrO₂ | DLC | 1.E+03 | 1.E+07 |
| example 9 | | | | | | | |
| Experimental | Probe memory | CeO₂ | TiN | CuCr_{0.5}Al_{0.5}O₂ | DLC | 1.E+03 | 1.E+07 |
| example 10 | | | | | | | |
| Experimental | Cross point | CeO₂ | TiN | CuCoO₂ | TiO₂ | 1.E+03 | 1.E+07 |
| example 11 | type memory | | | | | | |
| Experimental | Cross point | CeO₂ | TiN | CuFeO₂ | TiO₂ | 1.E+03 | 1.E+04 to |
| example 12 | type memory | | | | | | 1.E+05 |
| Experimental | Probe memory | CeO₂ | TiN | CuCoO₂ | SnO₂ | 1.E+03 | 1.E+02 to |
| example 13 | | | | | | | 1.E+05 |
| Experimental | Probe memory | Tb₄O₇ | LaNiO₃ | CuCoO₂ | DLC | 1.E+02 | 1.E+06 |
| example 14 | | | | | | | |
| Experimental | Probe memory | Ta₂O₅ | TiN | CuCoO₂ | DLC | 1.E+03 | 1.E+08 |
| example 15 | | | | | | | |
| Experimental | Probe memory | CeO₂ | RuO₂ | CuCoO₂ | DLC | 1.E+03 | 1.E+08 |
| example 16 | | | | | | | |

### OTHERS

According to the example of the present invention, since information recording (write) is only performed in a site (recording unit) to which an electric field is applied, information can be recorded in a very minute region with small power consumption.

Further, an erase is performed by applying heat, but if the materials according to the example of the present invention are used, a change of the crystal structure of the recording material is hardly generated, and therefore, the erase becomes possible with small power consumption.

Furthermore, according to the example of the present invention, the initial condition (insulator) is in the most stable condition in terms of energy, while, after a write, a conductive part is formed inside the insulator. Therefore, on the occasion of a read, the current flows intensively through the conductive part, so that it is possible to realize the recording principle with an extremely high sensing efficiency.

Thus, according to the example of the present invention, despite its very simple mechanism, it is possible to perform information recording based on the recording density, which has not been obtained by the conventional technique.

Therefore, the example of the invention provides a substantial industrial advantage as a next-generation technology overcoming the limit of the recording density of the existing nonvolatile memory.

The example of the present invention is not restricted to the above-described embodiment, and it can be embodied while transforming respective constituent elements in the scope without departing from the spirit of the invention. Further, various inventions can be constituted by appropriate combination of a plurality of constituent elements disclosed in the above embodiments. For instance, some constituent elements may be deleted from all the constituent elements disclosed in the above-described embodiments, or the constituent elements in different embodiments may be appropriately combined.

What is claimed is:

1. An information recording/reproducing device comprising:
a stacked structure which is comprised of an electrode layer and a recording layer;
a buffer layer which contacts with the electrode layer; and
a recording circuit which records data to the recording layer by generating a phase change in the recording layer,
wherein the recording layer is comprised of a complex compound having cations, and one of the cations is a transition element having “d” orbit where electrons are incompletely filled,
the recording layer is comprised of CuₓA_{y}X_{z} (0.1≦x≦1.1, 0.9≦y≦1.1, 1.8≦z≦2.2), where A includes one element selected from a group of Al, Ga, Sc, In, Y, La, Pr, Nd, Sm, Eu, Gd, Tb, Dy, Ho, Er, Tm, Yb, Lu, Ti, Ge, Sn, V, Cr, Mn, Fe, Co, Ni, Nb, Ta, Mo, W, Ru, Rh, and Pd, and X includes one element selected from a group of O, F, N, and S,
the recording layer includes a first chemical compound having a delafossite structure, and
the buffer layer is comprised of one of M₃N₄, M₃N₅, MN₂, M₄O₇, MO₂ and M₂O₅, where M includes one element selected from Si, Ge, Sn, Zr, Hf, Nb, Ta, Mo, W, Ce, and Tb.

2. The device according to claim 1, wherein the recording layer is oriented in a range of 45 degrees from a horizontal direction to a surface of the recording layer.

3. The device according to claim 1, wherein the recording layer is CuCoO₂.

4. The device according to claim 1, further comprising:
a second chemical compound which contacts with the first chemical compound, and has a vacant site of the X.

5. The device according to claim 4, wherein the second chemical compound is one of: [symbol]
ₓMZ₂, where [symbol] is a vacant site in which the X is accommodated, M includes one element selected from Ti, V, Cr, Mn, Fe, Co, Ni, Nb, Ta, Mo, W, Re, Ru, and Rh, Z includes one element selected from O, S, Se, N, Cl, Br, and I, and 0.3≦x≦1; [symbol]
ₓMZ₃, where [symbol] is the vacant site in which the X is accommodated, M includes one element selected from Ti, V, Cr, Mn, Fe, Co, Ni, Nb, Ta, Mo, W, Re, Ru, and Rh, Z includes one element selected from O, S, Se, N, Cl, Br, and I, and 1≦x≦2; [symbol]
ₓMZ₄, where [symbol] is the vacant site in which the X is accommodated, M includes one element selected from Ti, V, Cr, Mn, Fe, Co, Ni, Nb, Ta, Mo, W, Re, Ru, and Rh, Z includes one element selected from O, S, Se, N, Cl, Br, and I, and 1≦x≦2; and [symbol]
ₓMPO_{z}, where [symbol] is the vacant site in which the X is accommodated, M includes one element selected from Ti, V, Cr, Mn, Fe, Co, Ni, Nb, Ta, Mo, W, Re, Ru, and Rh, P is phosphorus element, 0 is oxygen element, 0.3≦x≦3, and 4≦z≦6.

6. The device according to claim 4, wherein the second chemical compound has one of a hollandite structure, ramsdellite structure, anatase structure, brookite structure, pyrolusite structure, ReO₃ structure, MoO_{1.5}PO₄ structure, TiO_{0.5}PO₄ structure, FePO₄ structure, βMnO₂ structure, γMnO₂ structure, λMnO₂ structure, and ilmenite structure.

7. The device according to claim 4, wherein the second chemical compound has ilmenite structure.

8. The device according to claim 1, wherein the recording circuit includes a probe to locally apply the voltage to a recording unit of the recording layer.

9. The device according to claim 1, wherein the recording circuit includes a word line and a bit line sandwiching the recording layer.

10. The device according to claim 1, wherein the recording circuit includes a MIS transistor, and the recording layer is disposed between a gate electrode of the MIS transistor and a gate insulating layer.

11. The device according to claim 1, wherein the recording circuit includes two diffusion layers in a semiconductor substrate, a semiconductor layer on the semiconductor substrate between the two diffusion layers, and a gate electrode above the semiconductor layer,
wherein the recording layer is disposed between the gate electrode and the semiconductor layer.
